(19) United States
(12) Patent Application Publication
(10) Pub. No.: US 2026/0107645 A1
(43) Pub. Date: Apr. 16, 2026

(54) DISPLAY APPARATUS

(71) Applicant: LG Display Co., Ltd., Seoul (KR)

(72) Inventor: Hyeongjun LIM, Paju-si (KR)

(73) Assignee: LG Display Co., Ltd., Seoul (KR)

(21) Appl. No.: 19/227,037

(22) Filed: Jun. 3, 2025

(30) Foreign Application Priority Data
Oct. 10, 2024 (KR) 10-2024-0137741

(51) Int. Cl. H10K 59/124; H10K 59/122; H10K 59/123; H10K 59/80

(52) U.S. Cl. CPC H10K 59/124; H10K 59/122; H10K 59/123; H10K 59/876; H10K 59/878; H10K 59/879

(57) ABSTRACT

In one configuration, the display apparatus includes a substrate that features a first sub-pixel, a second sub-pixel, and a third sub-pixel. Each of these sub-pixels contains both a light-emitting area and a non-light-emitting area. Positioned on the substrate is a second insulating layer, which includes a first reflective layer and a first gap-forming layer. A first anode electrode is located on the second insulating layer. Above this structure, a third insulating layer, a fourth insulating layer, a fifth insulating layer are sequentially stacked. Within the first sub-pixel, a first opening extends vertically through the third insulating layer, the fourth insulating layer, and the fifth insulating layer exposing both the first anode electrode and the second insulating layer beneath. The first reflective layer includes a plurality of inorganic films, each having a different refractive index.

### CROSS REFERENCE TO RELATED APPLICATION

The present application claims priority to Korean Patent Application No. 10-2024-0137741, filed October 10, 2024, the entire contents of which is incorporated herein for all purposes by this reference.

### BACKGROUND

### TECHNICAL FIELD

The present specification relates to a display apparatus.

### DESCRIPTION OF THE RELATED ART

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption than the LCD apparatus because it does not require a separate backlight. In addition, there is an advantage in that the OLED display apparatus can drive at a low voltage, have a fast response time, and especially have the inexpensive manufacturing cost.

Recently, demand for a display apparatus that requires augmented reality (AR), virtual reality (VR), or equivalent ultra-high resolution using such an OLED display apparatus is increasing.

### BRIEF SUMMARY

The present specification is directed to providing a display apparatus in which it is possible to suppress or prevent a lateral leakage current between adjacent pixels (or sub-pixels).

The present specification is also directed to providing a display apparatus in which it is possible to reduce or minimize a deviation and process error of a microcavity.

The present specification is also directed to providing a display apparatus in which it is possible to suppress or prevent light color mixing between pixels (or sub-pixels).

The present specification is also directed to providing a display apparatus in which it is possible to enable high-color reproduction by emitting more clear colors and suppress or prevent image quality from being degraded.

Technical benefits of the present specification are not limited to the above-described benefits, and other technical benefits may be inferred from the following embodiments.

According to one embodiment of the present specification, there is provided a display apparatus including a substrate having a first sub-pixel, a second sub-pixel, and a third sub-pixel, each of which includes a light-emitting area and a non-light-emitting area, a second insulating layer disposed on the substrate and including a first reflective layer and a firs gap-forming layer, a first anode electrode disposed on the second insulating layer, a third insulating layer formed on the second insulating layer, a fourth insulating layer formed on the third insulating layer, a fifth insulating layer disposed on the fourth insulating layer, and a first opening that extends into the third insulating layer, the fourth insulating layer, and the fifth insulating layer in a thickness direction and exposes the first anode electrode and the second insulating layer, wherein the first reflective layer includes a plurality of inorganic films having different refractive indexes.

According to another embodiment of the present specification, there is provided a display apparatus including a substrate, a second insulating layer formed on the substrate, an anode electrode disposed on the second insulating layer, a third insulating layer disposed on the second insulating layer, and an opening that extends into the third insulating layer in the thickness direction to expose the anode electrode and the second insulating layer, wherein the third insulating layer includes a plurality of inorganic layers forming a side surface of the opening, and the plurality of inorganic layers include a plurality of undercut areas including an undercut shape between adjacent inorganic layers on the side surface of the opening.

Detailed matters of other embodiments are included in the detailed description and accompanying drawings.

According to the embodiments of the present specification, it is possible to suppress or prevent a lateral leakage current between adjacent pixels (or sub-pixels).

According to the embodiments of the present specification, it is possible to reduce or minimize the deviation and process error of the microcavity.

According to the embodiments of the present specification, it is possible to suppress or prevent light color mixing between pixels (or sub-pixels).

According to the embodiments of the present specification, it is possible to enable high-color reproduction by emitting more clear colors and suppress or prevent image quality from being degraded.

According to the embodiments of the present specification, it is possible to enable high-color reproduction and reduce power consumption.

However, effects obtainable from the present specification are not limited to the above-described effects, and other effects that are not mentioned will be able to be clearly understood by those skilled in the art to which the present specification pertains based on the following description.

### BRIEF DESCRIPTION OF THE SEVERAL VIEWS OF THE DRAWINGS

FIG. 1 is a plan view of a display apparatus according to one embodiment.

FIG. 2 is a cross-sectional view along line A-A′ in FIG. 1.

FIG. 3 is a schematic view illustrating a microcavity of each sub-pixel.

FIG. 4 is a schematic enlarged view of area Q1 in FIG. 2 illustrating the reflection principle of a first reflective layer.

FIG. 5 is a cross-sectional view of an organic light-emitting diode OLED according to FIG. 2.

FIG. 6 is a cross-sectional view of an organic light-emitting diode OLED according to a modified example of FIG. 2.

FIG. 7 is an enlarged view of area Q2 in FIG. 2.

FIGS. 8 to 13 are cross-sectional views for each process in a method of manufacturing a display apparatus according to one embodiment.

FIG. 14 is a cross-sectional view of a display apparatus according to another embodiment.

FIG. 15 is a cross-sectional view of a display apparatus according to still another embodiment.

FIG. 16 is a cross-sectional view of a display apparatus according to yet another embodiment.

FIG. 17 is an enlarged view of area Q3 in FIG. 16.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween. To further elaborate, the terms "connected" and "coupled" are intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms “in contact,” "coupled" should be interpreted in the same manner.

The same reference numerals indicate the same components. The term “and/or” includes all one or more combinations that may be defined by the associated configurations.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

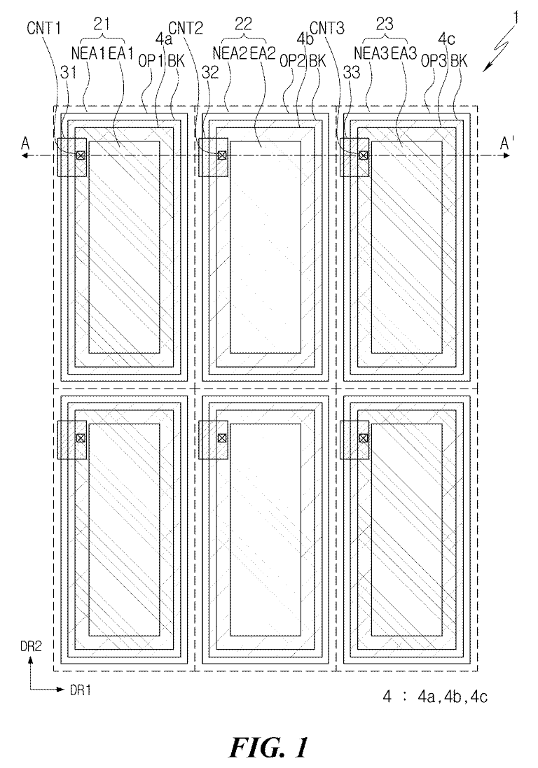

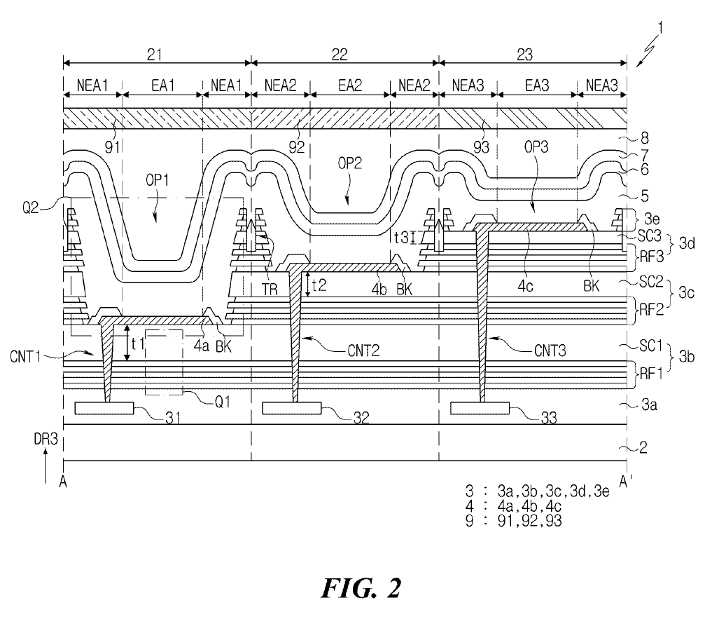

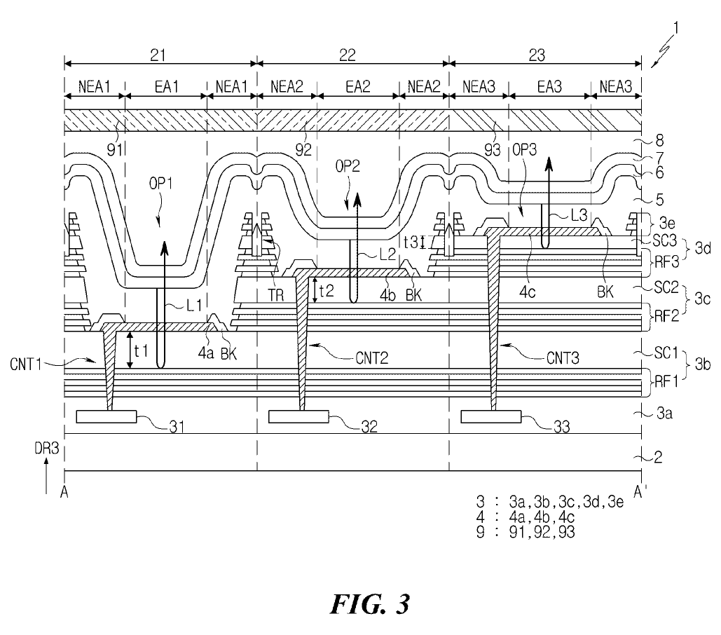

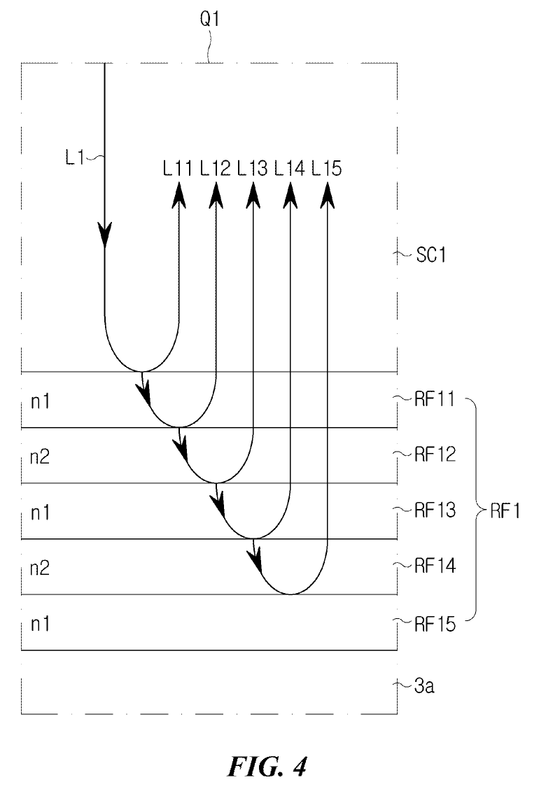

FIG. 1 is a plan view of a display apparatus according to one embodiment. FIG. 2 is a cross-sectional view along line A-A′ in FIG. 1. FIG. 3 is a schematic view illustrating a microcavity of each sub-pixel. FIG. 4 is a schematic enlarged view of area Q1 in FIG. 2 illustrating the reflection principle of a first reflective layer.

FIG. 4 illustrates the reflection principle of a first reflective layer RF1, but the description of the first reflective layer RF1 may be applied to a second reflective layer RF2 and a third reflective layer RF3 in the same manner.

Referring to FIGS. 1 to 4, a display apparatus 1 according to one embodiment includes a substrate 2, an insulating layer 3 (3a, 3b, 3c, 3d, and 3e), an anode electrode 4 (4a, 4b, and 4c), a common light-emitting layer 5, and a cathode electrode 6.

A plurality of sub-pixels 21, 22, and 23 are formed on the substrate 2. The plurality of sub-pixels 21, 22, and 23 may form one pixel. The plurality of pixels may be formed on the substrate 2.

The plurality of sub-pixels 21, 22, and 23 include a first sub-pixel 21, a second sub-pixel 22, and a third sub-pixel 23. The first sub-pixel 21, the second sub-pixel 22, and the third sub-pixel 23 may be disposed sequentially, alternately, and repeatedly in a first direction DR1. Each of the first sub-pixel 21, the second sub-pixel 22, and the third sub-pixel 23 may be disposed repeatedly in a second direction DR2.

Since the first sub-pixel 21, the second sub-pixel 22, and the third sub-pixel 23 may be arranged sequentially, the second sub-pixel 22 may be disposed adjacent to one side, for example, the left side of the first sub-pixel 21, and the third sub-pixel 23 may be disposed adjacent to one side, for example, the left side of the second sub-pixel 22.

Throughout the present specification, when two sub-pixels are disposed adjacent to each other, it should be construed to mean that no other sub-pixels are disposed between the two sub-pixels.

The first sub-pixel 21 may be provided to emit red (R) light, the second sub-pixel 22 may be provided to emit green (G) light, and the third sub-pixel 23 may be provided to emit blue (B) light, but the embodiments of the present specification are not necessarily limited thereto.

FIG. 1 illustrates an example in which a pixel includes only three sub-pixels 21, 22, and 23, but the embodiments of the present specification are not limited thereto, and the pixel may include four sub-pixels. When the pixel includes four sub-pixels, the pixel may further include a fourth sub-pixel provided to emit white (W) light.

Each of the first to third sub-pixels 21, 22, and 23 may be provided to have the same size. For example, each of the first to third sub-pixels 21, 22, and 23 may be provided to have the same width and the same height.

Here, the width may refer to a horizontal direction (the first direction DR1) based on FIG. 1, and the height may refer to a direction (the second direction DR2) perpendicular to the width based on FIG. 1, but the embodiments of the present specification are not necessarily limited thereto. The first direction DR1 may intersect the second direction DR2, and a third direction DR3 may intersect the first direction DR1 and the second direction DR2. The third direction DR3 may refer to a thickness direction of the display apparatus 1, but is not limited thereto.

The first direction DR1, the second direction DR2, and the third direction DR3 should be understood as relative directions and are not limited to embodiments of the present specification.

FIG. 1 illustrates each sub-pixel 21, 22, or 23 having a height in the second direction DR2 that is greater than a width in the first direction DR1 and a stripe type in which the sub-pixels 21, 22, and 23 are disposed sequentially and repeatedly in the first direction DR1, but the flat surface shapes and arrangement of the sub-pixels 21, 22, and 23 are not limited thereto and may be diverse.

For example, two sub-pixels selected from the sub-pixels 21, 22, and 23 may be disposed adjacent to each other in the first direction DR1, and the remaining one may be disposed at one or the other side of the two sub-pixels in the second direction DR2. In this case, the two sub-pixels may extend in the second direction DR2, and the remaining one may extend in the first direction DR1, but the embodiments of the present specification are not limited thereto.

That is, each sub-pixel 21, 22, or 23 may be disposed in at least one selected from, for example, a stripe type, a planar S-stripe type, a pentile type, a diamond structure type, etc.

A bank BK may be disposed in each of the first sub-pixel 21, the second sub-pixel 22, and the third sub-pixel 23. The bank BK may define light-emitting areas EA1, EA2, and EA3 of the sub-pixels 21, 22, and 23.

The bank BK is illustrated as being formed of a single layer, but is not limited thereto, and the bank BK may be formed of multiple layers. The bank BK may be formed of an inorganic insulation material, but is not limited thereto.

The sub-pixels 21, 22, and 23 may include the light-emitting areas EA1, EA2, and EA3 and non-light-emitting areas NEA1, NEA2, and NEA3, respectively. A first sub-pixel 21 may include a first light-emitting area EA1 and a first non-light-emitting area NEA1 around the first light-emitting area EA1. A second sub-pixel 22 may include a second light-emitting area EA2 and a second non-light-emitting area NEA2 around the second light-emitting area EA2. The third sub-pixel 23 may include a third light-emitting area EA3 and a third non-light-emitting area NEA3 around the third light-emitting area EA3. Each light-emitting area EA1, EA2, or EA3 may be the same as an area exposed from the bank BK of the anode electrode 4a, 4b, or 4c to be described below.

The anode electrode 4 is patterned for each sub-pixel 21, 22, or 23. That is, one anode electrode 4 is formed in the first sub-pixel 21, another anode electrode 4 is formed in the second sub-pixel 22, and still another anode electrode 4 is formed in the third sub-pixel 23.

The anode electrode 4 may include a first anode electrode 4a, a second anode electrode 4b, and a third anode electrode 4c. The first anode electrode 4a, the second anode electrode 4b, and the third anode electrode 4c may be disposed in the sub-pixel 21, 22, and 23, respectively.

The anode electrode 4 may serve as an anode of the display apparatus 1. The bank BK may be provided to cover an edge of the anode electrode 4 disposed in each of the first to third sub-pixels 21, 22, and 23 to distinguish the first sub-pixel 21, the second sub-pixel 22, and the third sub-pixel 23.

The display apparatus 1 may have reflectors (reflective layers RF1, RF2, and RF3) with different distances from the cathode electrode 6, thereby further increasing light extraction efficiency using the microcavity characteristic.

The microcavity characteristic refers to a characteristic that, when distances between the reflectors (the reflective layers RF1, RF2, and RF3) and the cathode electrode 6 are an integer multiple of a half wavelength (λ/2) of light emitted from the sub-pixels 21, 22 and 23, constructive interference occurs to amplify the light, and when a reflection and re-reflection process is repeated between the reflectors (the reflective layers RF1, RF2, and RF3) and the cathode electrode 6, a degree of light being amplified continuously increases, thereby increasing the external extraction efficiency of light.

The common light-emitting layer 5 may be provided to emit white light. For example, the common light-emitting layer 5 may be provided to emit white light by having a two-stack structure including a blue light-emitting layer, a yellow-green light-emitting layer, and a charge generation layer or a three-stack structure including a blue light-emitting layer, a green light-emitting layer, a red light-emitting layer, and a charge generation layer, but is not necessarily limited thereto, and may be formed of multiple layers exceeding 3 stacks as long as it may emit white light.

The common light-emitting layer 5 may be formed as a common layer across the first to third sub-pixels 21, 22, and 23.

The cathode electrode 6 is used to generate an electric field with the anode electrode 4 and may serve as a cathode. The cathode electrode 6 may be disposed on an upper surface of the common light-emitting layer 5, which is opposite to a lower surface of the common light-emitting layer 5 that comes into contact with the anode electrode 4 and provided as a common layer throughout the first to third sub-pixels 21, 22, and 23.

In the case of a top emission type, the cathode electrode 6 may be provided as a first electrode, and in the case of a bottom emission type, the cathode electrode 6 may be provided as an opaque cathode electrode including a reflective material. In the case of the top emission type, the cathode electrode 6 may be formed as a cathode electrode including a translucent material to increase light extraction efficiency using the microcavity characteristic. Since the display apparatus 1 increases light extraction efficiency using the microcavity characteristic in the top emission type, an example in which the cathode electrode 6 is formed as a cathode electrode including a translucent material will be described.

A color filter layer 9 is provided in each of the first to third sub-pixels 21, 22, and 23 to block a specific color from light emitted from the light-emitting layer of each sub-pixel. The color filter layer 9 may include a first color filter 91 provided in the first sub-pixel 21, a second color filter 92 provided in the second sub-pixel 22, and a third color filter 93 provided in the third sub-pixel 23.

The first color filter 91 may be provided to block light of other colors not including red (R) light. In this case, the first color filter 91 may be provided as a red color filter. The second color filter 92 may be provided to block light of other colors not including green (G) light. In this case, the second color filter 92 may be provided as a green color filter. The third color filter 93 may be provided to block light of other colors not including blue (B) light. In this case, the third color filter 93 may be provided as a blue color filter. However, the embodiments of the present specification are not necessarily limited thereto.

The first to third color filters 91, 92, and 93 provided in the first to third sub-pixels 21, 22, and 23, respectively, may be provided in the same size as the respective sub-pixels or provided by being reduced or expanded at a predetermined ratio to each sub-pixel.

Transistors 31, 32, and 33 may be disposed in the non-light-emitting areas NEA1, NEA2, and NEA3 of the sub-pixels 21, 22, and 23, respectively. For example, at least parts of the transistors 31, 32, and 33 may be disposed in the light-emitting areas EA1, EA2, and EA3.

The anode electrodes 4a, 4b, and 4c and the transistors 31, 32, and 33 that are disposed in the sub-pixels 21, 22, and 23, respectively, may correspond to each other. Through contact holes CNT1, CNT2, and CNT3 disposed in the sub-pixels 21, 22, and 23, respectively, the anode electrodes 4a, 4b, and 4c may be electrically connected to the corresponding transistors 31, 32, and 33, respectively. The contact holes CNT1, CNT2, and CNT3 may be disposed in the non-light-emitting areas NEA1, NEA2, and NEA3, but are not limited thereto.

In the present embodiment, the anode electrodes 4a, 4b, and 4c come into direct contact with the transistors 31, 32, and 33, respectively, but a method by which the anode electrodes 4a, 4b, and 4c are electrically connected to the transistors 31, 32, and 33 is not limited thereto.

For example, since at least one connection electrode may be further disposed between each of the anode electrodes 4a, 4b, and 4c and each of the transistors 31, 32, and 33, the anode electrodes 4a, 4b, and 4c and the transistors 31, 32, and 33 may be electrically connected through the connection electrode.

The transistors 31, 32, and 33 may include first to third transistors 31, 32, and 33 corresponding to the first to third sub-pixels 21, 22, and 23, respectively.

The first anode electrode 4a may be electrically connected in contact with the first transistor 31 through a first contact hole CNT1. The second anode electrode 4b may be electrically connected in contact with the second transistor 32 through a second contact hole CNT2. The third anode electrode 4c may be electrically connected in contact with the third transistor 33 through a third contact hole CNT3.

In the light-emitting areas EA1, EA2, and EA3, surface heights of the anode electrodes 4a, 4b, and 4c disposed in the sub-pixels 21, 22, and 23, respectively, may be different. A surface height of the third anode electrode 4c disposed in the third light-emitting area EA3 of the third sub-pixel 23 may be greater than a surface height of the second anode electrode 4b disposed in the second light-emitting area EA2 of the second sub-pixel 22. The surface height of the second anode electrode 4b disposed in the second light-emitting area EA2 of the second sub-pixel 22 may be greater than a surface height of the first anode electrode 4a disposed in the first light-emitting area EA1 of the first sub-pixel 21.

The anode electrodes 4a, 4b, and 4c disposed in the sub-pixels 21, 22, and 23, respectively, may be disposed on different layers in the light-emitting areas EA1, EA2, and EA3. In the first light-emitting area EA1, the first anode electrode 4a may be disposed on a second insulating layer 3b and may come into direct contact with the second insulating layer 3b. In the second light-emitting area EA2, the second anode electrode 4b may be disposed on a third insulating layer 3c and may come into direct contact with the third insulating layer 3c. In the third light-emitting area EA3, the third anode electrode 4c may be disposed on a fourth insulating layer 3d and may come into direct contact with the fourth insulating layer 3d.

A trench TR may be disposed between the sub-pixels 21, 22, and 23 (or between the light-emitting areas EA1, EA2, and EA3 of the sub-pixels 21, 22, and 23. In a plan view, the trench TR may extend between the sub-pixels 21, 22, and 23 in the first direction DR1 and the second direction DR2.

The trench TR may be defined by a fifth insulating layer 3e and the fourth insulating layer 3d. The trench TR may be formed in a groove or recess shape by removing at least parts of the fifth insulating layer 3e and the fourth insulating layer 3d. For example, the trench TR may be formed in a shape which extends into the fifth insulating layer 3e in the thickness direction (the third direction DR3) and in which a part of the fourth insulating layer 3d is removed.

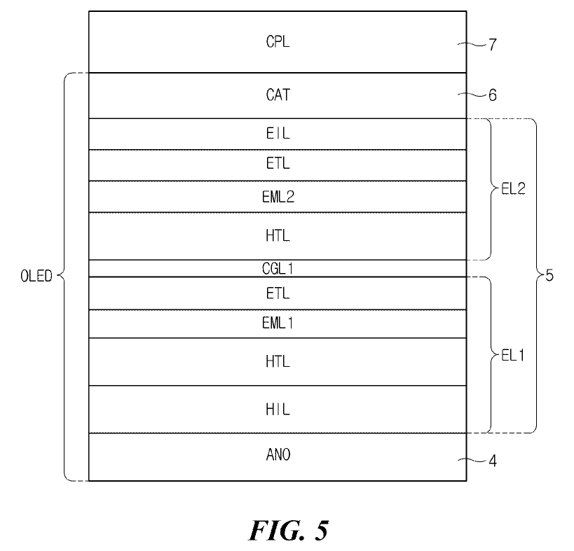

As the trench TR is disposed between the sub-pixels 21, 22, and 23, even when the common light-emitting layer 5 and the cathode electrode 6 are disposed across the sub-pixels 21, 22, and 23, a first stack EL1 (see FIG. 5) and a first charge generation layer CGL1 (see FIG. 5) are separated in each sub-pixel 21, 22, or 23, and a second stack EL2 (see FIG. 5) may be disposed between the first charge generation layer CGL1 (see FIG. 5) and the cathode electrode 6.

Accordingly, it is possible to prevent a lateral leakage current between sub-pixels 21, 22, and 23, prevent a short circuit between the first charge generation layer CGL1 and the cathode electrode 6, and prevent light color mixing.

Hereinafter, the stacking structure of the display apparatus 1 according to one embodiment will be described in detail.

The display apparatus 1 according to one embodiment includes the substrate 2, the insulating layer 3, the anode electrode 4, the bank BK, the common light-emitting layer 5, the cathode electrode 6, a capping layer 7, an encapsulation layer 8, and the color filter layer 9.

The substrate 2 may be a plastic film, a glass substrate, or a semiconductor substrate, such as silicon.

The substrate 2 may be formed of a transparent material or an opaque material. The first sub-pixel 21, the second sub-pixel 22, and the third sub-pixel 23 are provided on the substrate 2. The first sub-pixel 21 may be provided to emit red (R) light, the second sub-pixel 22 may be provided to emit blue (B) light, and the third sub-pixel 23 may be provided to emit green (G) light.

Since the display apparatus 1 according to one embodiment is configured in a so-called top emission type in which emitted light is emitted upward, both a transparent material and an opaque material may be used as a material of the substrate 2. The color filters 91, 92, and 93 may be respectively provided above the first to third sub-pixels 21, 22, and 23 from which light is emitted to transmit light of the above colors.

The insulating layer 3 is formed on the substrate 2. The insulating layer 3 may include a plurality of insulating layers 3a, 3b, 3c, 3d, and 3e. Hereinafter, the insulating layer 3 is described as including the first to fifth insulating layers 3a, 3b, 3c, 3d, and 3e, but is not limited thereto, and an additional insulating layer may be further disposed between the first to fifth insulating layers 3a, 3b, 3c, 3d, and 3e.

The first insulating layer 3a is disposed on the substrate 2, and circuit elements including the plurality of thin film transistors 31, 32, and 33, various signal lines, capacitors, etc., are provided in the first insulating layer 3a of each sub-pixel 21, 22, or 23. Each of the plurality of transistors 31, 32, and 33 may be formed as a thin film transistor, but is not limited thereto.

The signal lines may include a gate line, a data line, a power line, and a reference line, and the transistors 31, 32, and 33 may include a switching transistor, a driving transistor, and a sensing transistor. Each of the sub-pixels 21, 22, and 23 is defined by an intersection structure of gate lines and data lines.

The switching transistor is switched according to a gate signal supplied to the gate line to supply a data voltage supplied from the data line to the driving transistor.

The driving transistor is switched according to the data voltage supplied from the switching transistor to generate a data current from a power source supplied from the power line and supply the data current to the anode electrode 4.

The sensing transistor serves to detect a threshold voltage deviation of the driving transistor, which causes the degradation of image quality, and supplies the current of the driving transistor to the reference line in response to a sensing control signal supplied from the gate line or a separate sensing line.

The capacitor serves to maintain the data voltage supplied to the driving transistor for one frame and is connected to each of a gate terminal and a source terminal of the driving transistor.

A first transistor 31, a second transistor 32, and a third transistor 33 are respectively disposed in the sub-pixels 21, 22, and 23 in the first insulating layer 3a. The first transistor 31 may be connected to the first anode electrode 4a disposed in the first sub-pixel 21 to apply a driving voltage for emitting light of a color corresponding to the first sub-pixel 21.

The second transistor 32 may be connected to the second anode electrode 4b disposed in the second sub-pixel 22 to apply a driving voltage for emitting light of a color corresponding to the second sub-pixel 22.

The third transistor 33 may be connected to the third anode electrode 4c disposed in the third sub-pixel 23 to apply a driving voltage for emitting light of a color corresponding to the third sub-pixel 23.

When receiving the gate signal from the gate line using each of the transistors 31, 32, and 33, each of the first sub-pixel 21, the second sub-pixel 22, and the third sub-pixel 23 supplies a predetermined current to the light-emitting layer according to the data voltage of the data line. Accordingly, the light-emitting layer of each of the first sub-pixel 21, the second sub-pixel 22, and the third sub-pixel 23 may emit light with a predetermined brightness according to the predetermined current.

The first insulating layer 3a may protect the transistors 31, 32, and 33. The first insulating layer 3a may be formed of an inorganic insulation material, but is not necessarily limited thereto and may be formed of an organic insulation material. The transistors 31, 32, and 33 may be located in the first insulating layer 3a. For example, the first insulating layer 3a may be formed of an inorganic material, such as silicon nitride (SiNₓ), silicon oxide (SiOₓ), aluminum oxide (Al₂O₃), etc., but the embodiments of the present specification are not limited thereto.

The second to fourth insulating layers 3b, 3c, and 3d may be sequentially stacked on the first insulating layer 3a. The second to fourth insulating layers 3b, 3c, and 3d may include the reflective layers RF1, RF2, and RF3 and gap-forming layers SC1, SC2, and SC3, respectively.

The reflective layers RF1, RF2, and RF3 of the second to fourth insulating layers 3b, 3c, and 3d may be distributed Bragg reflectors (DBR) including a plurality of layers having different refractive indexes.

The gap-forming layers SC1, SC2, and SC3 of the second to fourth insulating layers 3b, 3c, and 3d may have different thicknesses. Accordingly, microcavity can be satisfied in each of the sub-pixels 21, 22, and 23 that emit light of different colors.

The second insulating layer 3b may be disposed on the first insulating layer 3a. For example, the second insulating layer 3b may be formed of an inorganic material, such as silicon nitride (SiNₓ), silicon oxide (SiOₓ), aluminum oxide (Al₂O₃), etc., but the embodiments of the present specification are not limited thereto.

The second insulating layer 3b may include the first reflective layer RF1 and a first gap-forming layer SC1. The first reflective layer RF1 may be disposed on the first insulating layer 3a, and the first gap-forming layer SC1 may be disposed on the first reflective layer RF1. The first reflective layer RF1 may be disposed between the first insulating layer 3a and the first gap-forming layer SC1.

The first reflective layer RF1 may serve as a reflector. The first reflective layer RF1 may include a plurality of inorganic films having different refractive indexes. The plurality of inorganic films having different refractive indexes may be alternately stacked.

The first reflective layer RF1 may have a structure in which a low-refractive index layer and a high-refractive index layer are alternately stacked. The low-refractive index layer and the high-refractive index layer have different refractive indexes, and a refractive index of the high-refractive index layer may be greater than a refractive index of the low-refractive index layer. Here, the low-refractive index and the high-refractive index may refer to relative refractive indexes.

The first reflective layer RF1 may have a total of at least five low-refractive index layers and high-refractive index layers. The first reflective layer RF1 may have a total of five to fifty low-refractive index layers and high-refractive index layers, but is not limited thereto.

In the present embodiment, the first reflective layer RF1 is described as having a plurality of low-refractive index layers and a plurality of high-refractive index layers and being formed of a total of five layers, but is not limited thereto.

A thickness of each layer forming the first reflective layer RF1 may be formed as a thickness that is an integer multiple of 1/4 of the wavelength (λ) of light emitted from the first sub-pixel 21. In this case, since reflection (and diffraction) occurs between the low-refractive index layer and the high-refractive index layer that have different refractive indexes and constructive interference can occur, the first reflective layer RF1 may serve as a reflector.

For example, when the first sub-pixel 21 emits red (R) light, the thickness of each layer forming the first reflective layer RF1 may be formed as a thickness that is an integer multiple of 1/4 of the wavelength (λ) of the red (R) light.

The embodiments of the present specification are not limited thereto, but, for example, the low-refractive index layer may be formed of silicon dioxide (SiO₂), and the high-refractive index layer may be formed of silicon nitride (SiNₓ) or titanium dioxide (TiO₂).

The first sub-pixel 21 may emit first light L1. The emitted first light L1 may travel from the common light-emitting layer 5 toward the first reflective layer RF1. When the first reflective layer RF1 is formed of a Bragg reflector, the first light L1 may be reflected from the first reflective layer RF1.

Specifically, the first reflective layer RF1 may include 11^{th} to 15^{th} inorganic layers RF11 to RF15 having different refractive indexes. The 11^{th} to 15^{th} inorganic layers RF11 to RF15 may be sequentially stacked from the first gap-forming layer SC1 toward the first insulating layer 3a.

The 11^{th} inorganic layer RF11, a 13^{th} inorganic layer RF13, and the 15^{th} inorganic layer RF15 may have the same first refractive index n1. A 12^{th} inorganic layer RF12 and a 14^{th} inorganic layer RF14 may have the same second refractive index n2. The first refractive index n1 may be more than the second refractive index n2, but is not limited thereto, and the first refractive index n1 may be less than the second refractive index n2.

The 11^{th} to 15^{th} inorganic layers RF11 to RF15 may have different refractive indexes. A thickness of each of the 11^{th} to 15^{th} inorganic layers RF11 to RF15 may be formed as a thickness that is an integer multiple of 1/4 of the wavelength (λ) of the first light L1. In this case, the first light L1 traveling toward the first reflective layer RF1 may be reflected (and diffracted) at a boundary of each inorganic layer. The light reflected (and diffracted) at the boundary of each inorganic layer may constructively interfere with each other.

For example, a part of the first light L1 may be reflected at a boundary between the first gap-forming layer SC1 and the 11^{th} inorganic layer RF11 to become 11^{th} reflected light L11. A part of the first light L1 that has passed through the 11^{th} inorganic layer RF11 may be reflected at a boundary between the 11^{th} inorganic layer RF11 and the 12^{th} inorganic layer RF12 to become 12^{th} reflected light L12. A part of the first light L1 that has passed through the 12^{th} inorganic layer RF12 may be reflected at a boundary between the 12^{th} inorganic layer RF12 and the 13^{th} inorganic layer RF13 to become 13^{th} reflected light L13. A part of the first light L1 that has passed through the 13^{th} inorganic layer RF13 may be reflected at a boundary between the 13^{th} inorganic layer RF13 and the 14^{th} inorganic layer RF14 to become 14^{th} reflected light L14. A part of the first light L1 that has passed through the 14^{th} inorganic layer RF14 may be reflected at a boundary between the 14^{th} inorganic layer RF14 and the 15^{th} inorganic layer RF15 to become 15^{th} reflected light L15.

The 11^{th} inorganic layer RF11, the 13^{th} inorganic layer RF13, and the 15^{th} inorganic layer RF15 may be formed of silicon nitride (SiNₓ) or titanium dioxide (TiO₂), and the 12^{th} inorganic layer RF12 and the 14^{th} inorganic layer RF14 may be formed of silicon dioxide (SiO₂), but the material of each inorganic layer is not limited thereto.

When a thickness of each of the 11^{th} to 15^{th} inorganic layers RF11 to RF15 is formed as a thickness that is an integer multiple of 1/4 of the wavelength (λ) of the first light L1, the 11^{th} to 15^{th} reflected light L11 to L15 may mutually constructively interfere with each other, and the first reflective layer RF1 may serve as a reflector, and thus the first light L1 may be reflected by the first reflective layer RF1.

When the reflector of the first light L1 emitted from the first sub-pixel 21 is formed of an inorganic film (an inorganic insulating film) rather than a metal, separate patterning may not be necessary, and thus it is possible to reduce or minimize a process error and a microcavity deviation, thereby improving the reliability of the display apparatus 1.

In each of the inorganic layers RF11 to RF15 of the first reflective layer RF1, adjacent inorganic layers may be formed to have a high selectivity. The high-refractive index layer and the low-refractive index layer may be alternately disposed, and the high-refractive index layer and the low-refractive index layer may have different etching rates. The first gap-forming layer SC1 may be formed by including a material having a different etching rate from the adjacent 11^{th} inorganic layer RF11.

The first gap-forming layer SC1 may have a first thickness t1. The first gap-forming layer SC1 may have a thickness that can satisfy a microcavity in the first sub-pixel 21.

For example, the first sub-pixel 21 may emit the first light L1 that is red (R) light. The first light L1 may be emitted from the common light-emitting layer 5 of the first sub-pixel 21 and may travel toward the first reflective layer RF1. The first gap-forming layer SC1 may be disposed between the common light-emitting layer 5 and the first reflective layer RF1 to adjust a gap between the cathode electrode 6 and the first reflective layer RF1.

The first gap-forming layer SC1 may be adjusted according to the first thickness t1 so that the gap between the cathode electrode 6 and the first reflective layer RF1 is an integer multiple of the half wavelength (λ/2) of the first light L1 emitted from the first sub-pixel 21.

The first gap-forming layer SC1 may be adjusted so that the gap between the cathode electrode 6 and the first reflective layer RF1 has a microcavity corresponding to the color of the light emitted from the first sub-pixel 21. Accordingly, it is possible to further increase the light extraction efficiency of the light emitted from the first sub-pixel 21.

For example, when the first light L1 emitted from the first sub-pixel 21 is red (R) light, the first gap-forming layer SC1 may be formed so that the gap between the cathode electrode 6 and the first reflective layer RF1 is an integer multiple of the half wavelength (λ/2) of the red (R) light.

Accordingly, the gap between the cathode electrode 6 and the first reflective layer RF1 may have a thickness that can satisfy a microcavity. In this case, the first thickness t1 of the first gap-forming layer SC1 may be greater than a second thickness t2 of the second gap-forming layer SC2 and a third thickness t3 of the third gap-forming layer SC3.

The third insulating layer 3c may be disposed on the second insulating layer 3b. For example, the third insulating layer 3c may be formed of an inorganic material, such as silicon nitride (SiNₓ), silicon oxide (SiOₓ), aluminum oxide (Al₂O₃), etc., but the embodiments of the present specification are not limited thereto.

The third insulating layer 3c may include the second reflective layer RF2 and a second gap-forming layer SC2. The second reflective layer RF2 may be disposed on the second insulating layer 3b, and the second gap-forming layer SC2 may be disposed on the second reflective layer RF2. The second reflective layer RF2 may be disposed between the second insulating layer 3b and the second gap-forming layer SC2.

The second reflective layer RF2 may serve as a reflector. The second reflective layer RF2 may include a plurality of inorganic films having different refractive indexes. The plurality of inorganic films having different refractive indexes may be alternately stacked. The configuration and reflection principle of the second reflective layer RF2 may be substantially the same as the configuration and reflection principle of the first reflective layer RF1.

The second reflective layer RF2 may have a structure in which a low-refractive index layer and a high-refractive index layer are alternately stacked. The low-refractive index layer and the high-refractive index layer have different refractive indexes, and a refractive index of the high-refractive index layer may be greater than a refractive index of the low-refractive index layer. Here, the low-refractive index and the high-refractive index may refer to relative refractive indexes.

The second reflective layer RF2 may have a total of at least five low-refractive index layers and high-refractive index layers. The second reflective layer RF2 may have a total of five to fifty low-refractive index layers and high-refractive index layers, but is not limited thereto.

In the present embodiment, the second reflective layer RF2 is described as having a plurality of low-refractive index layers and a plurality of high-refractive index layers and being formed of a total of five layers, but is not limited thereto.

A thickness of each layer forming the second reflective layer RF2 may be formed as a thickness that is an integer multiple of 1/4 of the wavelength (λ) of light emitted from the second sub-pixel 22. In this case, since reflection (and diffraction) occurs between the low-refractive index layer and the high-refractive index layer that have different refractive indexes and constructive interference can occur, the second reflective layer RF2 may serve as a reflector.

For example, when the second sub-pixel 22 emits green (G) light, the thickness of each layer forming the second reflective layer RF2 may be formed as a thickness that is an integer multiple of 2/4 of the wavelength (λ) of the green (G) light.

The embodiments of the present specification are not limited thereto, but, for example, the low-refractive index layer may be formed of silicon dioxide (SiO₂), and the high-refractive index layer may be formed of silicon nitride (SiNₓ) or titanium dioxide (TiO₂).

The second sub-pixel 22 may emit second light L2. The emitted second light L2 may travel from the common light-emitting layer 5 toward the second reflective layer RF2. When the second reflective layer RF2 is formed of a Bragg reflector, the second light L2 may be reflected from the second reflective layer RF2.

When the thickness of each of the low-refractive index layers and the high-refractive index layers of the second reflective layer RF2 is formed as a thickness that is an integer multiple of 1/4 of the wavelength (λ) of the second light L2, the second reflective layer RF2 may serve as a reflector, and thus the second light L2 may be reflected by the second reflective layer RF2.

When the reflector of the second light L2 emitted from the second sub-pixel 22 is formed of an inorganic film (an inorganic insulating film) rather than a metal, separate patterning may not be necessary, and thus it is possible to reduce or minimize a process error and a microcavity deviation, thereby improving the reliability of the display apparatus 1.

Each inorganic layer of the second reflective layer RF2 may be formed to have a high etching rate (selectivity). The high-refractive index layer and the low-refractive index layer may be alternately disposed, and the high-refractive index layer and the low-refractive index layer may have different etching rates. The second gap-forming layer SC2 may be formed by including a material having a different etching rate from the inorganic layer of the second reflective layer RF2 disposed closest thereto.

The second gap-forming layer SC2 may have the second thickness t2. The second gap-forming layer SC2 may have a thickness that can satisfy a microcavity in the second sub-pixel 22.

For example, the second sub-pixel 22 may emit the second light L2 that is green (G) light. The second light L2 may be emitted from the common light-emitting layer 5 of the second sub-pixel 22 and may travel toward the second reflective layer RF2. The second gap-forming layer SC2 may be disposed between the common light-emitting layer 5 and the second reflective layer RF2 to adjust a gap between the cathode electrode 6 and the second reflective layer RF2.

The second gap-forming layer SC2 may be adjusted according to the second thickness t2 so that the gap between the cathode electrode 6 and the second reflective layer RF2 is an integer multiple of the half wavelength (λ/2) of the second light L2 emitted from the second sub-pixel 22.

The second gap-forming layer SC2 may be adjusted so that the gap between the cathode electrode 6 and the second reflective layer RF2 has a microcavity corresponding to the color of the light emitted from the second sub-pixel 22. Accordingly, it is possible to further increase the light extraction efficiency of the light emitted from the second sub-pixel 22.

For example, when the second light L2 emitted from the second sub-pixel 22 is green (G) light, the second gap-forming layer SC2 may be formed so that the gap between the cathode electrode 6 and the second reflective layer RF2 is an integer multiple of the half wavelength (λ/2) of the green (G) light.

Accordingly, the gap between the cathode electrode 6 and the second reflective layer RF2 may have a thickness that can satisfy a microcavity. In this case, the second thickness t2 of the second gap-forming layer SC2 may be greater than the third thickness t3 of the third gap-forming layer SC3.

The fourth insulating layer 3d may be disposed on the third insulating layer 3c. For example, the fourth insulating layer 3d may be formed of an inorganic material, such as silicon nitride (SiNₓ), silicon oxide (SiOₓ), aluminum oxide (Al₂O₃), etc., but the embodiments of the present specification are not limited thereto.

The fourth insulating layer 3d may include the third reflective layer RF3 and the third gap-forming layer SC3. The third reflective layer RF3 may be disposed on the third insulating layer 3c, and the third gap-forming layer SC3 may be disposed on the third reflective layer RF3. The third reflective layer RF3 may be disposed between the third insulating layer 3c and the third gap-forming layer SC3.

The third reflective layer RF3 may serve as a reflector. The third reflective layer RF3 may include a plurality of inorganic films having different refractive indexes. The plurality of inorganic films having different refractive indexes may be alternately stacked. The configuration and reflection principle of the third reflective layer RF3 may be substantially the same as the configuration and reflection principle of the first reflective layer RF1.

The third reflective layer RF3 may have a structure in which a low-refractive index layer and a high-refractive index layer are alternately stacked. The low-refractive index layer and the high-refractive index layer have different refractive indexes, and a refractive index of the high-refractive index layer may be greater than a refractive index of the low-refractive index layer. Here, the low-refractive index and the high-refractive index may refer to relative refractive indexes.

The third reflective layer RF3 may have a total of at least five low-refractive index layers and high-refractive index layers. The third reflective layer RF3 may have a total of five to fifty low-refractive index layers and high-refractive index layers, but is not limited thereto.

In the present embodiment, the third reflective layer RF3 is described as having a plurality of low-refractive index layers and a plurality of high-refractive index layers and being formed of a total of five layers, but is not limited thereto.

A thickness of each layer forming the third reflective layer RF3 may be formed as a thickness that is an integer multiple of 1/4 of the wavelength (λ) of light emitted from the third sub-pixel 23. In this case, since reflection (and diffraction) occurs between the low-refractive index layer and the high-refractive index layer that have different refractive indexes and constructive interference can occur, the third reflective layer RF3 may serve as a reflector.

For example, when the third sub-pixel 23 emits blue (B) light, the thickness of each layer forming the third reflective layer RF3 may be formed as a thickness that is an integer multiple of 3/4 of the wavelength (λ) of the blue (B) light.

The embodiments of the present specification are not limited thereto, but, for example, the low-refractive index layer may be formed of silicon dioxide (SiO₂), and the high-refractive index layer may be formed of silicon nitride (SiNₓ) or titanium dioxide (TiO₃).

The third sub-pixel 23 may emit third light L3. The emitted third light L3 may travel from the common light-emitting layer 5 toward the third reflective layer RF3. When the third reflective layer RF3 is formed of a Bragg reflector, the third light L3 may be reflected from the third reflective layer RF3.

When the thickness of each of the low-refractive index layers and the high-refractive index layers of the third reflective layer RF3 is formed as a thickness that is an integer multiple of 1/4 of the wavelength (λ) of the third light L3, the third reflective layer RF3 may serve as a reflector, and thus the third light L3 may be reflected by the third reflective layer RF3.

When the reflector of the third light L3 emitted from the third sub-pixel 23 is formed of an inorganic film (an inorganic insulating film) rather than a metal, separate patterning may not be necessary, and thus it is possible to reduce or minimize a process error and a microcavity deviation, thereby improving the reliability of the display apparatus 1.

Each inorganic layer of the third reflective layer RF3 may be formed to have a high etching rate (selectivity). The high-refractive index layer and the low-refractive index layer may be alternately disposed, and the high-refractive index layer and the low-refractive index layer may have different etching rates. The third gap-forming layer SC3 may be formed by including a material having a different etching rate from the inorganic layer of the third reflective layer RF3 disposed closest thereto.

The third gap-forming layer SC3 may have the third thickness t3. The third gap-forming layer SC3 may have a thickness that can satisfy a microcavity in the third sub-pixel 23.

For example, the third sub-pixel 23 may emit the third light L3 that is blue (B) light. The third light L3 may be emitted from the common light-emitting layer 5 of the third sub-pixel 23 and may travel toward the third reflective layer RF3. The third gap-forming layer SC3 may be disposed between the common light-emitting layer 5 and the third reflective layer RF3 to adjust a gap between the cathode electrode 6 and the third reflective layer RF3.

The third gap-forming layer SC3 may be adjusted according to the third thickness t3 so that the gap between the cathode electrode 6 and the third reflective layer RF3 is an integer multiple of the half wavelength (λ/2) of the third light L3 emitted from the third sub-pixel 23.

The third gap-forming layer SC3 may be adjusted so that the gap between the cathode electrode 6 and the third reflective layer RF3 has a microcavity corresponding to the color of the light emitted from the third sub-pixel 23. Accordingly, it is possible to further increase the light extraction efficiency of the light emitted from the third sub-pixel 23.

For example, when the third light L3 emitted from the third sub-pixel 23 is blue (B) light, the third gap-forming layer SC3 may be formed so that the gap between the cathode electrode 6 and the third reflective layer RF3 is an integer multiple of the half wavelength (λ/2) of the blue (B) light. Accordingly, the gap between the cathode electrode 6 and the third reflective layer RF3 may have a thickness that can satisfy a microcavity.

The fifth insulating layer 3e may be disposed on the fourth insulating layer 3d. The fifth insulating layer 3e may be formed of a plurality of layers including different materials. Hereinafter, the fifth insulating layer 3e is described as being formed of four layers, but the number of layers forming the fifth insulating layer 3e is not limited thereto.

Adjacent layers of the fifth insulating layer 3e may have a high etching rate (selectivity) with respect to each other. Each layer of the fifth insulating layer 3e may include substantially the same material as the high-refractive index layer and the low-refractive index layer of the reflective layers RF1, RF2, and RF3.

Each inorganic layer of the second reflective layer RF2, the second gap-forming layer SC2, each inorganic layer of the third reflective layer RF3, the third gap-forming layer SC3, and each inorganic layer of the fifth insulating layer 3e may have a high etching rate with respect to adjacent layers.

Each inorganic layer of the second reflective layer RF2, the second gap-forming layer SC2, each inorganic layer of the third reflective layer RF3, the third gap-forming layer SC3, and each inorganic layer of the fifth insulating layer 3e may sequentially and alternately have different etching rate.

In the first sub-pixel 21, the first insulating layer 3a, the first transistor 31 disposed in the first insulating layer 3a, the second insulating layer 3b disposed on the first insulating layer 3a, the third insulating layer 3c disposed on the second insulating layer 3b, the first anode electrode 4a disposed on the second insulating layer 3b, the bank BK disposed on the first anode electrode 4a, the fourth insulating layer 3d disposed on the third insulating layer 3c, and the fifth insulating layer 3e disposed on the fourth insulating layer 3d may be sequentially disposed on the substrate 2.

The third insulating layer 3c, the fourth insulating layer 3d, and the fifth insulating layer 3e may define a first opening OP1 exposing the second insulating layer 3b. The first opening OP1 may pass through the third insulating layer 3c, the fourth insulating layer 3d, and the fifth insulating layer 3e in the thickness direction (the third direction DR3) to expose the second insulating layer 3b.

That is, the first opening OP1 may expose the second insulating layer 3b, and sidewalls of the first opening OP1 may be formed of the third insulating layer 3c, the fourth insulating layer 3d, and the fifth insulating layer 3e.

The first anode electrode 4a may be disposed in the first opening OP1. The first anode electrode 4a may be disposed on the second insulating layer 3b exposed by the first opening OP1 and may come into direct contact with an upper surface of the second insulating layer 3b.

The first anode electrode 4a may be electrically connected in contact with the first transistor 31 by the first contact hole CNT1 that extends into the second insulating layer 3b and part of the first insulating layer 3a in the thickness direction (the third direction DR3) to expose the first transistor 31.

In the second sub-pixel 22, the first insulating layer 3a, the second transistor 32 disposed in the first insulating layer 3a, the second insulating layer 3b disposed on the first insulating layer 3a, the third insulating layer 3c disposed on the second insulating layer 3b, the second anode electrode 4b disposed on the third insulating layer 3c, the bank BK disposed on the second anode electrode 4b, the fourth insulating layer 3d disposed on the third insulating layer 3c, and the fifth insulating layer 3e disposed on the fourth insulating layer 3d may be sequentially disposed on the substrate 2.

The fourth insulating layer 3d and the fifth insulating layer 3e may define a second opening OP2 exposing the third insulating layer 3c. The second opening OP2 may pass through the fourth insulating layer 3d and the fifth insulating layer 3e in the thickness direction (the third direction DR3) to expose the third insulating layer 3c.

That is, the second opening OP2 may expose the third insulating layer 3c, and sidewalls of the second opening OP2 may be formed of the fourth insulating layer 3d and the fifth insulating layer 3e.

The second anode electrode 4b may be disposed in the second opening OP2. The second anode electrode 4b may be disposed on the third insulating layer 3c exposed by the second opening OP2 and may come into direct contact with an upper surface of the third insulating layer 3c.

The second anode electrode 4b may be electrically connected in contact with the second transistor 32 by the second contact hole CNT2 that extends into a part of the first insulating layer 3a, the second insulating layer 3b , and the third insulating layer 3c in the thickness direction (the third direction DR3) to expose the second transistor 32.

In the third sub-pixel 23, the first insulating layer 3a, the third transistor 33 disposed in the first insulating layer 3a, the second insulating layer 3b disposed on the first insulating layer 3a, the third insulating layer 3c disposed on the second insulating layer 3b, the fourth insulating layer 3d disposed on the third insulating layer 3c, the third anode electrode 4c disposed on the fourth insulating layer 3d, the bank BK disposed on the third anode electrode 4c, and the fifth insulating layer 3e disposed on the fourth insulating layer 3d may be sequentially disposed on the substrate 2.

The fifth insulating layer 3e may define a third opening OP3 exposing the fourth insulating layer 3d. The third opening OP3 may pass through the fifth insulating layer 3e in the thickness direction (the third direction DR3) to expose the fourth insulating layer 3d.

That is, the third opening OP3 may expose the fourth insulating layer 3d, and sidewalls of the third opening OP3 may be formed of the fifth insulating layer 3e.

The third anode electrode 4c may be disposed in the third opening OP3. The third anode electrode 4c may be disposed on the fourth insulating layer 3d exposed by the third opening OP3 and may come into direct contact with an upper surface of the fourth insulating layer 3d.

The third anode electrode 4c may be electrically connected in contact with the third transistor 33 by the third contact hole CNT3 that extends into a part of the first insulating layer 3a, the second insulating layer 3b, the third insulating layer 3c, and the fourth insulating layer 3d in the thickness direction (the third direction DR3) to expose the third transistor 33.

The display apparatus 1 according to one embodiment may be provided in the top emission type, and to this end, the reflective layers RF1, RF2, and RF3 may be provided to reflect light emitted from the common light-emitting layer 5 upward.

Each reflective layer RF1, RF2, or RF3 may reflect light, which is emitted toward the reflective layer RF1, RF2, or RF3 among the light emitted from the common light-emitting layer 5 of the sub-pixel 21, 22, or 23, toward the cathode electrode 6 or the encapsulation layer 8. In addition, each reflective layer RF1, RF2, or RF3 is formed to implement the microcavity characteristic through reflection and re-reflection with the cathode electrode 6. To this end, each reflective layer RF1, RF2, or RF3 may be formed as a reflector for reflecting light.

Since the reflective layers RF1, RF2, and RF3 are disposed at relatively lower locations than the common light-emitting layer 5 for emitting light, the reflective layers RF1, RF2, and RF3 may reflect the light emitted from the common light-emitting layer 5 upward. Here, upward may refer to a direction in which a user may perceive light, for example, a side to which the encapsulation layer 8 or the color filter layer 9 is disposed. Accordingly, it is possible to further increase the light efficiency of the first sub-pixel 21, the second sub-pixel 22, and the third sub-pixel 23 compared to when the reflective layers RF1, RF2, and RF3 are not present, and the user may perceive a high-luminance image, that is, a clear image, through the increased light efficiency.

As described above, the display apparatus 1 can further increase light extraction efficiency using the microcavity characteristics by including the reflective layers RF1, RF2, and RF3.

A distance between the first reflective layer RF1 and the anode electrode 4 may be greater than a distance between the second reflective layer RF2 and the anode electrode 4. The distance between the second reflective layer RF2 and the anode electrode 4 may be greater than a distance between the third reflective layer RF3 and the anode electrode 4.

The reason why the reflective layers RF1, RF2, and RF3 are formed to have various separation distances (or resonance distances) from the cathode electrode 6 is that the light extraction efficiency of different colors can be increased through reflection and re-reflection between the reflective layers RF1, RF2, and RF3 and the cathode electrode 6 according to the separation distances. Accordingly, it is possible to increase the light extraction efficiency of red light in the first sub-pixel 21, increase the light extraction efficiency of green light in the second sub-pixel 22, and increase the light extraction efficiency of blue light in the third sub-pixel 23.

The anode electrode 4 is disposed on the reflective layers RF1, RF2, and RF3. The anode electrode 4 is formed to supply holes to the common light-emitting layer 5. The anode electrode 4 may be provided to be transparent so that light reflected from the reflective layers RF1, RF2, and RF3 may travel upward. The anode electrode 4 may be formed of a transparent material, but is not limited thereto, and may be formed in the form of a thin film with a thin metal material. For example, the anode electrode 4 may include titanium nitride (TiN), but is not limited thereto. The anode electrode 4 may be formed of a very thin film so that the light reflected from the reflective layers RF1, RF2, and RF3 may travel upward. For example, a thickness of the anode electrode 4 may be about 5 nm or less. For example, the thickness of the anode electrode 4 may be about 3 nm or less, but is not limited thereto.

The anode electrode 4 may be electrically connected to the first to third transistors 31, 32, and 33 through the contact holes CNT1 to CNT3, respectively, so that a driving voltage provided by each of the first to third transistors 31, 32, and 33 may be applied to the anode electrode 4. The anode electrode 4 may supply holes to the common light-emitting layer 5 when the driving voltages are applied from the first to third transistors 31, 32, and 33.

The anode electrodes 4a, 4b, and 4c disposed in the sub-pixels 21, 22, and 23, respectively, may be disposed on different layers in the light-emitting areas EA1, EA2, and EA3.

The bank BK may be disposed on the anode electrode 4 (4a, 4b, and 4c). The bank BK may be formed of an inorganic material, such as silicon nitride (SiNₓ), silicon oxide (SiOₓ), aluminum oxide (Al₂O₃), etc., but the embodiments of the present specification are not limited thereto.

In the light-emitting areas EA1, EA2, and EA3, the bank BK may define the light-emitting areas EA1, EA2, and EA3 by exposing the upper surface of the anode electrode 4 (4a, 4b, and 4c). On the other hand, in the non-light-emitting areas NEA1, NEA2, and NEA3, the bank BK may cover the upper surfaces of the anode electrodes 4a, 4b, and 4c.

In each sub-pixel 21, 22, or 23, the entire area of the bank BK may be disposed in each opening OP1, OP2, or OP3, but is not limited thereto. The bank BK disposed in each sub-pixel 21, 22, or 23 may be patterned, and the entire area of each of the patterned banks BK may be disposed in one of the openings OP1, OP2, and OP3.

The common light-emitting layer 5 is formed on the anode electrode 4 and the bank BK. The common light-emitting layer 5 may also be formed on filling members disposed between the plurality of sub-pixels 21, 22, and 23. The common light-emitting layer 5 may come into contact with the upper surface of the anode electrode 4. The common light-emitting layer 5 may come into direct contact with the side surfaces and upper surface of the bank BK.

The organic light-emitting diode OLED according to one embodiment may include the anode electrode 4, the cathode electrode 6, and the common light-emitting layer 5 between the anode electrode 4 and the cathode electrode 6.

The common light-emitting layer 5 may be provided to emit white (W) light. To this end, the common light-emitting layer 5 may include a plurality of stacks for emitting light of different colors. Specifically, the common light-emitting layer 5 may include a first stack, a second stack, and a charge generation layer CGL provided between the first stack and the second stack.

The cathode electrode 6 is formed on the common light-emitting layer 5. The cathode electrode 6 may serve as a cathode of the display apparatus 1. Like the common light-emitting layer 5, the cathode electrode 6 is formed in each of the sub-pixels 21, 22, and 23 and between the sub-pixels 21, 22, and 23.

In the display apparatus 1 according to one embodiment, the cathode electrode 6 may be formed as a cathode electrode including a translucent material in order to implement white light with light efficiency in the top emission type. Accordingly, the microcavity effect can be obtained for each of the first to third sub-pixels 21, 22, and 23. When the cathode electrode 6 is formed as the cathode electrode including a translucent material, the microcavity effect can be obtained as light is reflected and re-reflected repeatedly between the cathode electrode 6 and the reflective layers RF1 RF2, and RF3, thereby increasing light extraction efficiency.

Meanwhile, since the cathode electrode 6 is formed on the upper surface of the common light-emitting layer 5, the cathode electrode 6 may be formed along a profile of the common light-emitting layer 5. Since the common light-emitting layer 5 is formed along the profile of the anode electrode 4 in the light-emitting area, the cathode electrode 6 may be eventually formed along the profile of the anode electrode 4. In addition, the capping layer 7 on the cathode electrode 6 may also be formed along a profile of the cathode electrode 6.

The capping layer 7 may be formed of an inorganic insulation material, but is not limited thereto. The capping layer 7 may be formed of a single layer, but is not limited thereto, and may be formed of multiple layers. The capping layer (CPL) 7 may be disposed on the cathode electrode (CAT) 6 to protect the organic light-emitting diode OLED.

The encapsulation layer 8 is formed on the cathode electrode 6 to prevent external moisture from penetrating the common light-emitting layer 5. The encapsulation layer 8 may be formed of an inorganic insulation material or formed in a structure in which an inorganic insulation material and an organic insulation material are alternately stacked, but is not necessarily limited thereto.

The color filter layer 9 is formed on the encapsulation layer 8. The color filter layer 9 may include the red (R) first color filter 91 provided in the first sub-pixel 21, the green (G) second color filter 92 provided in the second sub-pixel 22, and the blue (B) third color filter 93 provided in the third sub-pixel 23, but is not necessarily limited thereto.

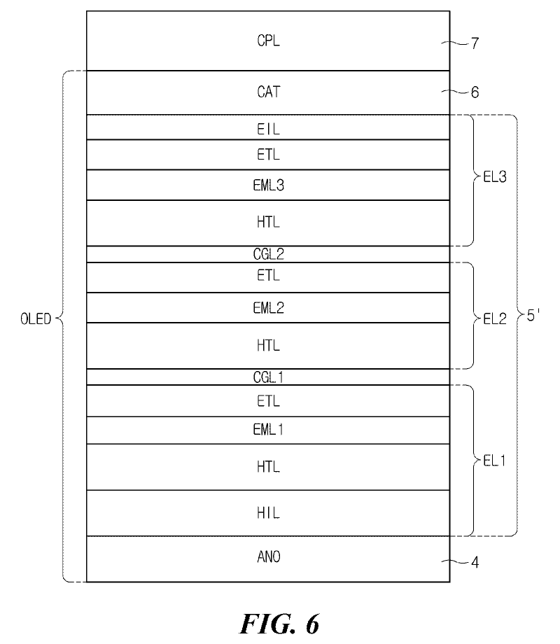

FIG. 5 is a cross-sectional view of an organic light-emitting diode OLED according to FIG. 2. FIG. 6 is a cross-sectional view of an organic light-emitting diode OLED according to a modified example of FIG. 2.

Referring to FIGS. 2 to 6, the common light-emitting layer 5 may include the first stack EL1, the second stack EL2, and the first charge generation layer CGL1, which are provided on the anode electrode (ANO) 4.

The first stack EL1 may be provided on the anode electrode 4 and configured in a structure in which a hole injecting layer HIL, a hole transporting layer HTL, a blue (B) light-emitting layer EML1, and an electron transporting layer ETL may be sequentially stacked.

The first stack EL1 may be disposed between the first sub-pixel 21 and the second sub-pixel 22 and between the second sub-pixel 22 and the third sub-pixel 23.

The first charge generation layer CGL1 serves to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metallic material as a dopant.

The second stack EL2 may be provided on the first stack EL1 and configured in a structure in which a hole transporting layer HTL, a yellow-green (YG) light-emitting layer EML2, an electron transporting layer ETL, and an electron injecting layer EIL are sequentially stacked.

The second stack EL2 may be disposed between the first sub-pixel 21 and the second sub-pixel 22 and between the second sub-pixel 22 and the third sub-pixel 23.

As a result, the common light-emitting layer 5 may be provided as a common layer across the first to third sub-pixels 21, 22, and 23 as illustrated in FIG. 2.

As illustrated in FIG. 6, a common light-emitting layer 5′ of the organic light-emitting diode OLED according to one embodiment may include the first stack EL1 provided on the anode electrode 4, the second stack EL2, a third stack EL3, the first charge generation layer CGL1 between the first stack EL1 and the second stack EL2, and a second charge generation layer CGL2 between the second stack EL2 and the third stack EL3.

The first stack EL1 may be provided on the anode electrode 4 and configured in a structure in which a hole injecting layer HIL, a hole transporting layer HTL, a blue (B) light-emitting layer EML1, and an electron transporting layer ETL may be sequentially stacked.

The first stack EL1 may be disposed between the first sub-pixel 21 and the second sub-pixel 22 and between the second sub-pixel 22 and the third sub-pixel 23, that is, on the bank BK.

The first charge generation layer CGL1 serves to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metallic material as a dopant.

The second stack EL2 may be provided on the first stack EL1 and configured in a structure in which a hole transporting layer HTL, a green (G) light-emitting layer EML2, and an electron transporting layer ETL are sequentially stacked.

The second stack EL2 may be disposed between the first sub-pixel 21 and the second sub-pixel 22 and disposed between the second sub-pixel 22 and the third sub-pixel 23, that is, on the bank BK.

The second charge generation layer CGL2 serves to supply charges to the second stack EL2 and the third stack EL3. The second charge generation layer CGL2 may include an N-type charge generation layer for supplying electrons to the second stack EL2 and a P-type charge generation layer for supplying holes to the third stack EL3. The N-type charge generation layer may include a metallic material as a dopant.

The third stack EL3 may be provided on the second stack EL2 and configured in a structure in which a hole transporting layer HTL, a red (R) light-emitting layer EML3, an electron transporting layer ETL, and an electron injecting layer EIL are sequentially stacked.

Even when the common light-emitting layer 5 is formed to be provided as a common layer across the first to third sub-pixels 21, 22, and 23, it is possible to suppress or prevent a leakage current between adjacent sub-pixels 21, 22, and 23 by the sidewalls of the first to third openings OP1, OP2, and OP3.

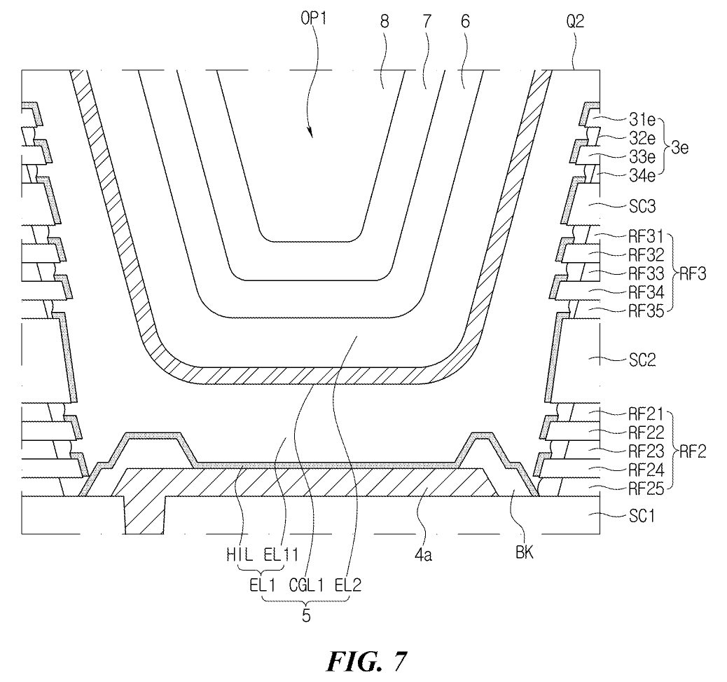

The detailed descriptions thereof will be given further with reference to FIG. 7.

FIG. 7 is an enlarged view of area Q2 in FIG. 2.

For convenience of description, only the anode electrode 4a and the hole injecting layer HIL of the common light-emitting layer 5 of the organic light-emitting diode OLED are separately illustrated in FIG. 7.

FIG. 7 is described based on the first opening OP1 of the first sub-pixel 21, but the description thereof may also be applied to the second opening OP2 of the second sub-pixel 22 and the third opening OP3 of the third sub-pixel 23 in substantially the same manner.

Referring to FIG. 2 and FIGS. 5-7, an organic layer EL11 may be disposed on the hole injecting layer HIL, the first charge generation layer CGL1 may be disposed on the organic layer EL11, and the second stack EL2 may be disposed on the first charge generation layer CGL1. Here, the organic layer EL11 may include the hole transporting layer HTL, the blue light-emitting layer EML1, and the electron transporting layer ETL of FIG. 5. The first stack EL1 may include the organic layer EL11 and the hole injecting layer HIL.

The hole injecting layer HIL may be patterned into a plurality of patterns in the first opening OP1, and the plurality of patterns may be disconnected without being connected.

Specifically, the first opening OP1 may be defined by a plurality of inorganic films, and adjacent inorganic films may have high etching rates with respect to each other. For example, an inorganic film having a first etching rate and an inorganic film having a second etching rate may be disposed alternately and sequentially, and the first etching rate and the second etching rate may be different.

The plurality of inorganic films defining the first opening OP1 may form the third insulating layer 3c, the fourth insulating layer 3d, and the fifth insulating layer 3e.

Accordingly, during the etching process of forming the first opening OP1, the plurality of inorganic films defining the first opening OP1 may be etched to different degrees. At the sidewalls of the first opening OP1, a plurality of under-cut shapes may be formed between adjacent inorganic films in the thickness direction (the third direction DR3).

The plurality of inorganic films defining the first opening OP1 may be formed so that a protruding inorganic film of which a side surface protrudes toward an inside of the first opening OP1 and a recessed inorganic film of which a side surface is recessed toward the inside of the first opening OP1 are disposed alternately and repeatedly in the thickness direction (the third direction DR3), but are not limited thereto. The side surface of the protruding inorganic film may protrude toward the inside of the first opening OP1 more than the side surface of the recessed inorganic film.

Specifically, the second reflective layer RF2 may include 21^{st} to 25^{th} inorganic layers RF21 to RF25. The 21^{st} inorganic layer RF21, a 23^{rd} inorganic layer RF23, and the 25^{th} inorganic layer RF25 may have the first etching rate, and a 22^{nd} inorganic layer RF22 and a 24^{th} inorganic layer RF24 may have the second etching rate. In addition, the second gap-forming layer SC2 may have the same second etching rate as the 22^{nd} inorganic layer RF22 and the 24^{th} inorganic layer RF24.

For example, for a specific etchant formed by etching the first opening OP1, the first etching rate may be greater than the second etching rate. During the process of forming the first opening OP1, the 21^{st} inorganic layer RF21, the 23^{rd} inorganic layer RF23, and the 25^{th} inorganic layer RF25 may be etched more than the 22^{nd} inorganic layer RF22, the 24^{th} inorganic layer RF24, and the second gap-forming layer SC2.

Accordingly, the side surface of the second gap-forming layer SC2 may protrude toward the inside of the first opening OP1 more than a side surface of the 21^{st} inorganic layer RF21, and the second gap-forming layer SC2 and the 21^{st} inorganic layer RF21 may have an undercut shape (or may include an undercut area including an undercut shape) at the sidewall of the first opening OP1.

A side surface of the 22^{nd} inorganic layer RF22 may protrude toward the inside of the first opening OP1 more than the side surface of the 21^{st} inorganic layer RF21 and a side surface of the 23^{rd} inorganic layer RF23, and the 22^{nd} inorganic layer RF22 and the 23^{rd} inorganic layer RF23 may have an undercut shape at the sidewall of the first opening OP1.

A side surface of the 24^{th} inorganic layer RF24 may protrude inward from the first opening OP1 more than the side surface of the 23^{rd} inorganic layer RF23 and a side surface of the 25^{th} inorganic layer RF25, and the 24^{th} inorganic layer RF24 and the 25^{th} inorganic layer RF25 may have an undercut shape at the sidewall of the first opening OP1.

In addition, the 21^{st} inorganic layer RF21, the 23^{rd} inorganic layer RF23, and the 25^{th} inorganic layer RF25 may have the same first refractive index n1. The 22^{nd} inorganic layer RF22 and the 24^{th} inorganic layer RF24 may have the same second refractive index n2. The first refractive index n1 may be more than the second refractive index n2, but is not limited thereto, and the first refractive index n1 may be less than the second refractive index n2. Accordingly, the second reflective layer RF2 may serve as a reflector.

The third reflective layer RF3 may include 31^{st} to 35^{th} inorganic layers RF31 to RF35. The 31^{st} inorganic layer RF31, a 33^{rd} inorganic layer RF33, and the 35^{th} inorganic layer RF35 may have the first etching rate, and a 32^{nd} inorganic layer RF32 and a 34^{th} inorganic layer RF34 may have the second etching rate. In addition, the third gap-forming layer SC3 may have the same second etching rate as the 32^{nd} inorganic layer RF32 and the 34^{th} inorganic layer RF34.

For example, for a specific etchant formed by etching the first opening OP1, the first etching rate may be greater than the second etching rate. During the process of forming the first opening OP1, the 31^{st} inorganic layer RF31, the 33^{rd} inorganic layer RF33, and the 35^{th} inorganic layer RF35 may be etched more than the 32^{nd} inorganic layer RF32, the 34^{th} inorganic layer RF34, and the third gap-forming layer SC3.

Accordingly, the side surface of the third gap-forming layer SC3 may protrude toward the inside of the first opening OP1 more than a side surface of the 31^{st} inorganic layer RF31, and the third gap-forming layer SC3 and the 31^{st} inorganic layer RF31 may have an undercut shape (or may include an undercut area including an undercut shape) at the sidewall of the first opening OP1.

A side surface of the 32^{nd} inorganic layer RF32 may protrude toward the inside of the first opening OP1 more than the side surface of the 31^{st} inorganic layer RF31 and a side surface of the 33^{th} inorganic layer RF33, and the 32^{nd} inorganic layer RF32 and the 33^{rd} inorganic layer RF33 may have an undercut shape at the sidewall of the first opening OP1.

A side surface of the 34^{th} inorganic layer RF34 may protrude toward the inside of the first opening OP1 more than the side surface of the 33^{rd} inorganic layer RF33 and a side surface of the 35^{th} inorganic layer RF35, and the 34^{th} inorganic layer RF34 and the 35^{th} inorganic layer RF35 may have an undercut shape at the sidewall of the first opening OP1.

In addition, the 31^{st} inorganic layer RF31, the 33^{rd} inorganic layer RF33, and the 35^{th} inorganic layer RF35 may have the same first refractive index n1. The 32^{nd} inorganic layer RF32 and the 34^{th} inorganic layer RF34 may have the same second refractive index n2. The first refractive index n1 may be more than the second refractive index n2, but is not limited thereto, and the first refractive index n1 may be less than the second refractive index n2. Accordingly, the third reflective layer RF3 may serve as a reflector.

The fifth insulating layer 3e may include first to fourth inorganic layers 31e to 34e. A second inorganic layer 32e and the fourth inorganic layer 34e may have the first etching rate, and the first inorganic layer 31e and a third inorganic layer 33e may have the second etching rate.

For example, for a specific etchant formed by etching the first opening OP1, the first etching rate may be greater than the second etching rate. During the process of forming the first opening OP1, the second inorganic layer 32e and the fourth inorganic layer 34e may be etched more than the first inorganic layer 31e and the third inorganic layer 33e.

A side surface of the first inorganic layer 31e may protrude toward the inside of the first opening OP1 more than a side surface of the second inorganic layer 32e, and the first inorganic layer 31e and the second inorganic layer 32e may have an undercut shape at the sidewall of the first opening OP1.

A side surface of the third inorganic layer 33e may protrude toward the inside of the first opening OP1 more than the side surface of the second inorganic layer 32e and a side surface of the fourth inorganic layer 34e, and the third inorganic layer 33e and the fourth inorganic layer 34e may have an undercut shape at the sidewall of the first opening OP1.

The common light-emitting layer 5 may be commonly disposed across all areas of the sub-pixels 21, 22, and 23, and the hole injecting layer HIL may also be commonly disposed across all areas of the sub-pixels 21, 22, and 23. The hole injecting layer HIL may be disposed on the first anode electrode 4a and the bank BK and disposed on the sidewalls of the first opening OP1 along the sidewalls of the first opening OP1.

Since the sidewall of the first opening OP1 is formed of a plurality of inorganic films and a plurality of undercut shapes are formed between adjacent inorganic films, the hole injecting layer HIL may be patterned and disposed to be disconnected in the undercut area of the sidewall of the first opening OP1 by step coverage.

The hole injecting layer HIL at the sidewall of the first opening OP1 may be formed as a plurality of separated patterns. The hole injecting layer HIL may be disposed on an inorganic layer protruding toward the inside of the first opening OP1 among the plurality of inorganic layers forming the sidewall of the first opening OP1, and the hole injecting layer HIL disposed on each of the protruding inorganic layers may be separately patterned so as not to be electrically connected.

For example, the separated patterns of the hole injecting layer HIL may be disposed on the side surfaces and upper surfaces of each of the first inorganic layer 31e, the third inorganic layer 33e, the 32^{nd} inorganic layer RF32, the 34^{th} inorganic layer RF34, the third gap forming layer SC3, the 22^{nd} inorganic layer RF22, the 24^{th} inorganic layer RF24, and the second gap-forming layer SC2, and the respective patterns may be separated.

The hole injecting layer HIL may be disposed directly on the first anode electrode 4a, disposed as a plurality of separated patterns at the sidewall of the first opening OP1, and separated from and may not be electrically connected to the hole injecting layers HIL disposed in the second sub-pixel 22 and the third sub-pixel 23 adjacent to the first sub-pixel 21.

Accordingly, it is possible to more smoothly suppress or prevent a lateral leakage current between the first sub-pixel 21, the second sub-pixel 22, and the third sub-pixel 23 adjacent to one another. In addition, it is possible to suppress or prevent light color mixing between the first sub-pixel 21, the second sub-pixel 22, and the third sub-pixel 23 adjacent to one another, thereby enabling high-color reproduction by emitting clearer colors, and suppressing or preventing the degradation of image quality. Accordingly, it is possible to reduce the power consumption of the display apparatus.

In addition, since the hole injecting layer HIL is separated through the plurality of inorganic films included in the insulating layer 3, a separate configuration is not required for separating the hole injecting layer HIL, and thus it is possible to increase an aperture ratio of each light-emitting area EA1, EA2, or EA3 or reduce or minimize the reduction in the aperture ratio and reducing or minimizing the process of manufacturing the display apparatus 1.

In addition, in the first opening OP1, an empty space may be defined between the inorganic film having the recessed side surface and the organic layer EL11, but the embodiments of the present specification are not limited thereto.

The second opening OP2 may be defined by the fourth insulating layer 3d and the fifth insulating layer 3e. Like the first opening OP1, at the side wall of the second opening OP2, the third reflective layer RF3 and the third gap-forming layer SC3 of the fourth insulating layer 3d and the fifth insulating layer 3e may have a plurality of under-cut shapes between adjacent inorganic films in the thickness direction (the third direction DR3).

The hole injecting layer HIL disposed in the second opening OP2 may be disposed directly on the second anode electrode 4b, disposed as a plurality of separated patterns at the sidewall of the second opening OP2, and separated from and may not be electrically connected to the hole injecting layers HIL disposed in the first sub-pixel 21 and the third sub-pixel 23 adjacent to the second sub-pixel 22.

Accordingly, it is possible to more smoothly suppress or prevent a lateral leakage current between the adjacent sub-pixels 21, 22, and 23, prevent light color mixing, enabling high-color reproduction by emitting more clear colors, and suppress or prevent the degradation of image quality. Accordingly, it is possible to reduce the power consumption of the display apparatus 1.

The third opening OP3 may be defined by the fifth insulating layer 3e. Like the first opening OP1, at the sidewall of the third opening OP3, the fifth insulating layer 3e may have a plurality of undercut shapes between adjacent inorganic films in the thickness direction (the third direction DR3).

The hole injecting layer HIL disposed in the third opening OP3 may be disposed directly on the third anode electrode 4c, disposed as a plurality of separated patterns at the sidewall of the third opening OP3, and separated from and may not be electrically connected to the hole injecting layers HIL disposed in the first sub-pixel 21 and the second sub-pixel 22 adjacent to the third sub-pixel 23.

Accordingly, it is possible to more smoothly suppress or prevent a lateral leakage current between the adjacent sub-pixels 21, 22, and 23, prevent light color mixing, enabling high-color reproduction by emitting more clear colors, and suppress or prevent the degradation of image quality. Accordingly, it is possible to reduce the power consumption of the display apparatus 1.

Hereinafter, a method of manufacturing the display apparatus 1 according to one embodiment will be described. While describing the method of manufacturing the display apparatus 1 according to one embodiment, the descriptions of parts already described in FIGS. 1 to 7 will be briefly given or omitted.

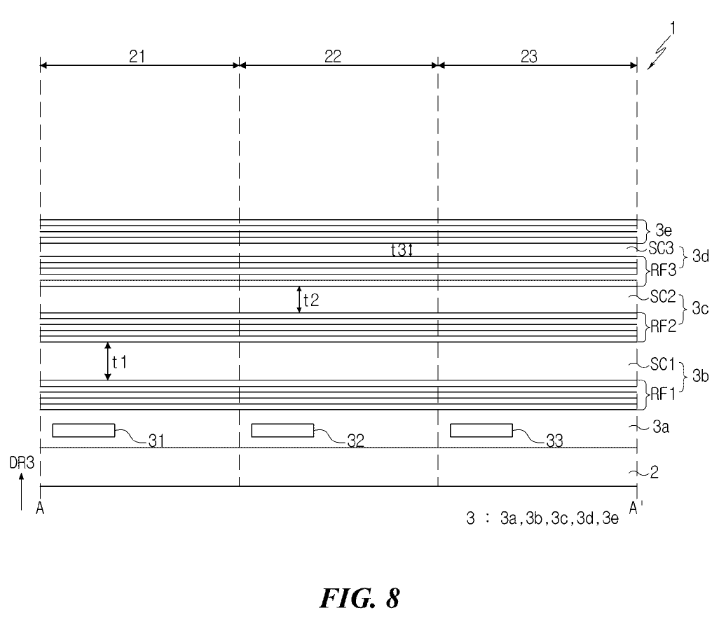

FIGS. 8 to 13 are cross-sectional views for each process in a method of manufacturing a display apparatus according to one embodiment.

First, referring to FIG. 8, the substrate 2 having the first to fifth insulating layers 3a, 3b, 3c, 3d, and 3e disposed thereon is provided. Circuit elements including the plurality of thin film transistors 31, 32, and 33, various signal lines, capacitors, and the like may be provided in the first insulating layer 3a of each sub-pixel 21, 22, or 23.

The first to fifth insulating layers 3a, 3b, 3c, 3d, and 3e may be sequentially stacked on the substrate 2. The first to fifth insulating layers 3a, 3b, 3c, 3d, and 3e may be disposed across the entire area of the substrate 2, but are not limited thereto.

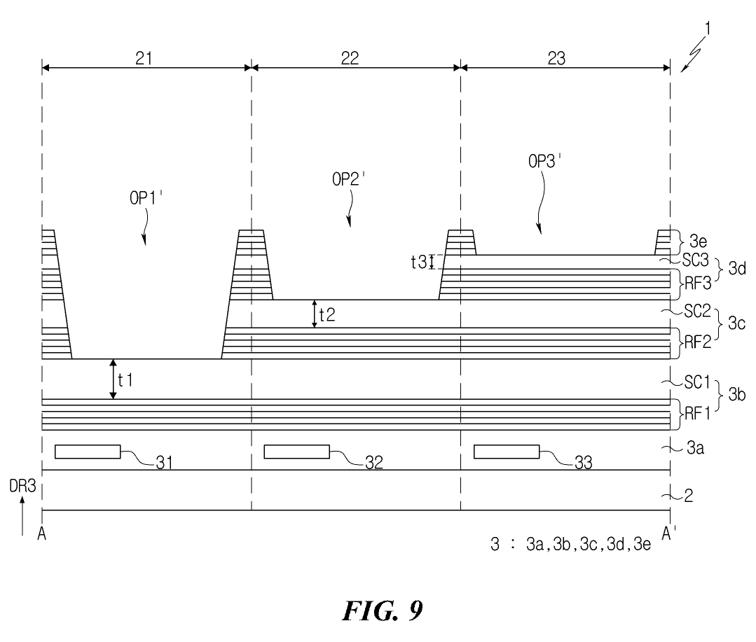

Subsequently, referring to FIG. 9, a first opening OP1′ exposing the second insulating layer 3b, a second opening OP2′ exposing the third insulating layer 3c, and a third opening OP3′ exposing the fourth insulating layer 3d are formed.

The first opening OP1′ may be disposed in the first sub-pixel 21, the second opening OP2′ may be disposed in the second sub-pixel 22, and the third opening OP3′ may be disposed in the third sub-pixel 23.

The first opening OP1′ may pass through the third insulating layer 3c, the fourth insulating layer 3d, and the fifth insulating layer 3e in the thickness direction (the third direction DR3) to expose the second insulating layer 3b and may be defined by the third insulating layer 3c, the fourth insulating layer 3d, and the fifth insulating layer 3e.

The second opening OP2′ may pass through the fourth insulating layer 3d and the fifth insulating layer 3e in the thickness direction (the third direction DR3) to expose the third insulating layer 3c and may be defined by the fourth insulating layer 3d, and the fifth insulating layer 3e.

The third opening OP3′ may pass through the fifth insulating layer 3e in the thickness direction (the third direction DR3) to expose the fourth insulating layer 3d and may be defined by the fifth insulating layer 3e.

A patterned first photoresist (not illustrated) may be disposed on the fifth insulating layer 3e, and the insulating layer 3 of an area exposed by the first photoresist (not illustrated) may be etched. Accordingly, the first opening OP1′, the second opening OP2′, and the third opening OP3′ may be formed.

However, the embodiments of the present specification are not limited thereto, and during the process of forming the first opening OP1′, the second opening OP2′, and the third opening OP3′, a plurality of photoresists may be used to etch the insulating layers 3c, 3d, and 3e, respectively.

The side surfaces of the inorganic films forming the sidewall of the first opening OP1′, the second opening OP2′, and the third opening OP3′ may be aligned, but are not limited thereto.

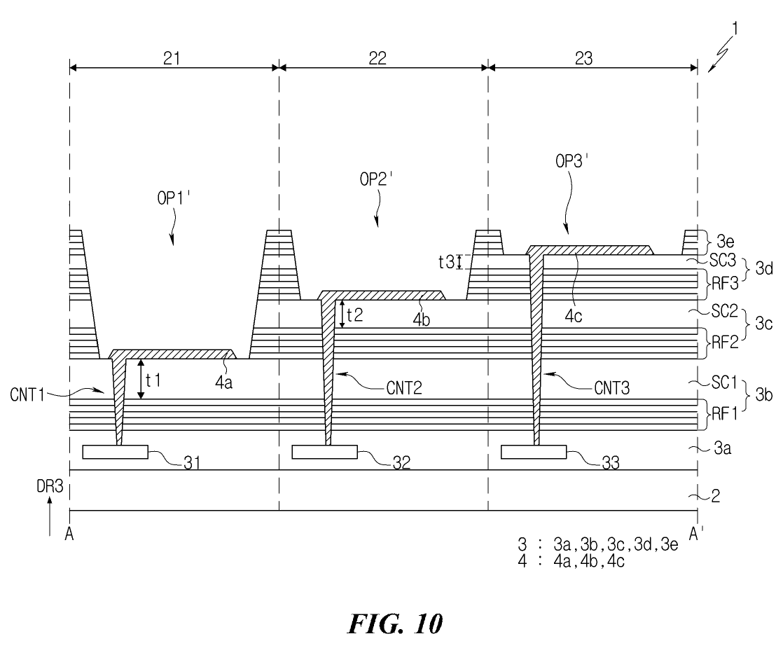

Subsequently, referring to FIG. 10, the first to third contact holes CNT1, CNT2, and CNT3) are formed, and the anode electrodes 4a, 4b, and 4c are patterned and disposed.

The first to third contact holes CNT1 to CNT3 may be formed in the non-light-emitting areas NEA1, NEA2, and NEA3, respectively. The first contact hole CNT1 may pass through the second insulating layer 3b and a part of the first insulating layer 3a in the thickness direction (the third direction DR3) to expose the first transistor 31. The second contact hole CNT2 may pass through the third insulating layer 3c, the second insulating layer 3b, and a part of the first insulating layer 3a in the thickness direction (the third direction DR3) to expose the second transistor 32. The third contact hole CNT3 may pass through the fourth insulating layer 3d, the third insulating layer 3c, the second insulating layer 3b, and a part of the first insulating layer 3a in the thickness direction (the third direction DR3) to expose the third transistor 33.

Subsequently, the anode electrodes 4a, 4b, and 4c are patterned and disposed inside the first opening OP1′, the second opening OP2′, and the third opening OP3′, respectively.

The anode electrode 4 before being patterned may be disposed on the second to fourth insulating layers 3b, 3c, 3d, and at least a part of the anode electrode 4 may be disposed in the first opening OP1′, the second opening OP2′, and the third opening OP3′. A patterned second photoresist (not illustrated) may be disposed on the anode electrode 4, a part of the anode electrode 4 exposed by the second photoresist (not illustrated) may be removed, and the anode electrode 4 may be patterned to form the anode electrodes 4a, 4b, and 4c. The second photoresist (not illustrated) may be removed by an ashing process.

The anode electrodes 4a, 4b, and 4c may be separately patterned, but are not limited thereto.

The anode electrodes 4a, 4b, and 4c may be formed through the same process (or mask) and may include the same material. The first anode electrode 4a may be disposed in the first sub-pixel 21, the second anode electrode 4b may be disposed in the second sub-pixel 22, and the third anode electrode 4c may be disposed in the third sub-pixel 23.

The first anode electrode 4a may be disposed in the first opening OP1′, the second anode electrode 4b may be disposed in the second opening OP2′, and the third anode electrode 4c may be disposed in the third opening OP3′.

The anode electrodes 4a, 4b, and 4c may fill the first to third contact holes CNT1, CNT2, and CNT3 and come into contact with the transistors 31, 32, and 33, respectively.

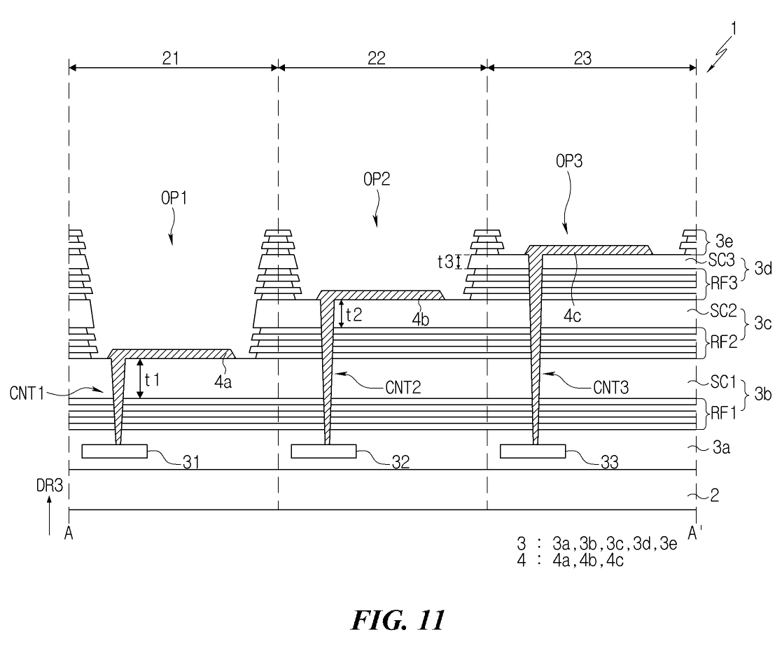

Subsequently, referring further to FIG. 11, a plurality of undercut shapes are formed on the sidewalls of each of the first opening OP1′, the second opening OP2′, and the third opening OP3′ of FIG. 10.

The inorganic films of the third to fifth insulating layers 3c, 3d, and 3e respectively forming the sidewalls of the first opening OP1′, the second opening OP2′, and the third opening OP3′ of FIG. 10 have different etching rates. An etchant capable of selectively etching only some of the inorganic films of each of the third to fifth insulating layers 3c, 3d, and 3e is used to selectively etch only some of the inorganic films of each of the third to fifth insulating layers 3c, 3d, and 3e.

Accordingly, the first opening OP1, the second opening OP2, and the third opening OP3 may be formed, and the sidewalls of each of the first opening OP1, the second opening OP2, and the third opening OP3 may include a plurality of undercut shapes.

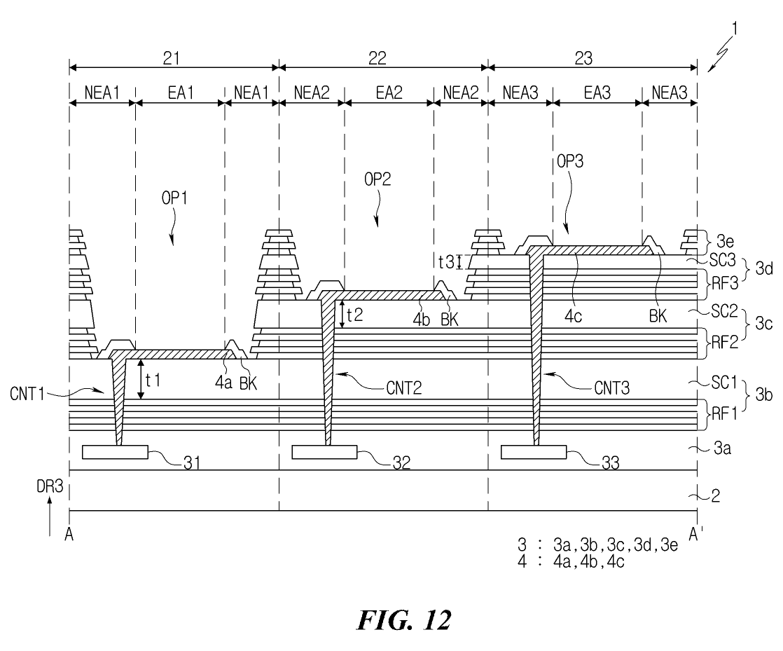

Subsequently, referring to FIG. 12, the bank BK is patterned and disposed on the anode electrodes 4a, 4b, and 4c.

The bank BK before being patterned may be disposed on the anode electrodes 4a, 4b, and 4c and the insulating layers 3b, 3c, and 3d on which the anode electrodes 4a, 4b, and 4c are disposed, and at least a part of the bank BK may be disposed in each of the openings OP1, OP2, and OP3. A patterned third photoresist (not illustrated) may be disposed on the bank BK, and a part of the bank BK exposed by the third photoresist (not illustrated) may be removed to expose the anode electrodes 4a, 4b, and 4c. Accordingly, the light-emitting areas EA1, EA2, and EA3 and the non-light-emitting areas NEA1, NEA2, and NEA3 may be formed. The third photoresist (not illustrated) may be removed by an ashing process.

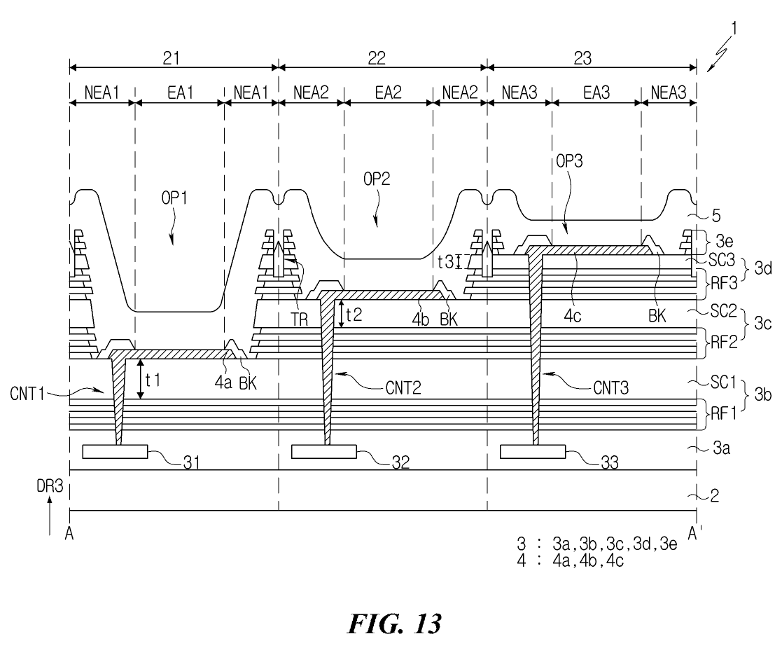

Subsequently, referring to FIG. 13, the trench TR is formed between the sub-pixel 21, 22, and 23, and the common light-emitting layer 5 is disposed.

At least parts of the insulating layers 3a, 3b, 3c, 3d, and 3e may be etched in the areas between the sub-pixel 21, 22, and 23 to form the trench TR.

After the trench TR is formed, the common light-emitting layer 5 is disposed on the anode electrodes 4a, 4b, and 4c and the bank BK. The common light-emitting layer 5 may be disposed across the entire area of the substrate 2, but is not limited thereto.

Even when the common light-emitting layer 5 is disposed across the entire area, the first stack EL1 (see FIG. 5) and the first charge generation layer CGL1 (see FIG. 5) may be separated in each sub-pixel 21, 22, or 23 by the trench TR, and the hole injecting layer HIL may be separated by each opening OP1, OP2, or OP3 in each sub-pixel 21, 22, or 23. Accordingly, it is possible to suppress or prevent a lateral leakage current between the adjacent sub-pixels 21, 22, and 23.

Referring further to FIG. 2, the cathode electrode 6, the capping layer 7, the encapsulation layer 8, and the color filter layer 9 may be further disposed sequentially on the common light-emitting layer 5.

Hereinafter, other embodiments of the present specification will be described. For contents that are substantially the same as those described with reference to FIGS. 1 to 13 among components included in other embodiments, the same reference numerals are given, and overlapping contents may be omitted or briefly described.

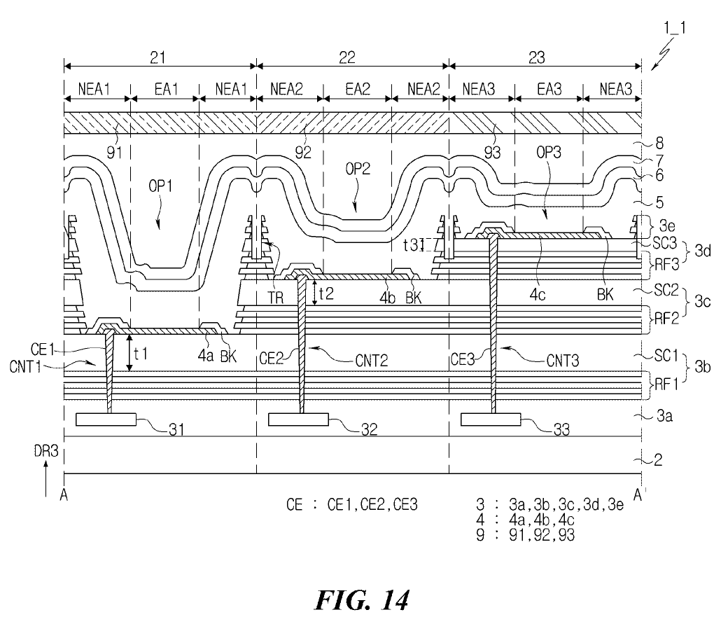

FIG. 14 is a cross-sectional view of a display apparatus according to still another embodiment.

Referring to FIG. 14, a display apparatus 1_1 according to the present embodiment may further include a connection electrode CE (CE1, CE2, and CE3) electrically connecting the anode electrodes 4a, 4b, and 4c to the transistors 31, 32, and 33.

Specifically, a first connection electrode CE1 may be disposed in the first sub-pixel 21 and may come into contact with the first transistor 31 by filling the first contact hole CNT1. The first anode electrode 4a may cover the first connection electrode CE1 and come into contact with the first connection electrode CE1. Through the first connection electrode CE1, the first anode electrode 4a and the first transistor 31 may be electrically connected.

A second connection electrode CE2 may be disposed in the second sub-pixel 22 and may come into contact with the second transistor 32 by filling the second contact hole CNT2. The second anode electrode 4b may cover the second connection electrode CE2 and come into contact with the second connection electrode CE2. Through the second connection electrode CE2, the second anode electrode 4b and the second transistor 32 may be electrically connected.

A third connection electrode CE3 may be disposed in the third sub-pixel 23 and may come into contact with the third transistor 33 by filling the third contact hole CNT3. The third anode electrode 4c may cover the third connection electrode CE3 and come into contact with the third connection electrode CE3. Through the third connection electrode CE3, the third anode electrode 4c and the third transistor 33 may be electrically connected.

Referring further to FIGS. 8 and 9, the first insulating layer 3a and the second insulating layer 3b may be sequentially disposed on the substrate 2, and then the second insulating layer 3b and the first insulating layer 3a may be etched to form the first contact hole CNT1, and a deposited first conductive layer (not illustrated) may be patterned to form the first connection electrode CE1.

Thereafter, the third insulating layer 3c may be disposed to cover the first connection electrode CE1, the first insulating layer 3a, the second insulating layer 3b and the third insulating layer 3c may be etched to form the second contact hole CNT2, and the deposited second conductive layer (not illustrated) may be patterned to form the second connection electrode CE2.

Thereafter, the fourth insulating layer 3d may be disposed to cover the second connection electrode CE2, the first insulating layer 3a, the second insulating layer 3b, the third insulating layer 3c, and the fourth insulating layer 3d may be etched to form the third contact hole CNT3, and the deposited third conductive layer (not illustrated) may be patterned to form the third connection electrode CE3.

Thereafter, the fifth insulating layer 3e may be disposed to cover the third connection electrode CE3, and as illustrated in FIG. 9, the first to third openings OP1′, OP2′, and OP3′ may be formed to expose the connection electrodes CE1, CE2, and CE3, respectively.

In this case, since the anode electrode 4 and each transistor 31, 32, or 33 are connected by the connection electrode CE, the electrical connection between the anode electrode 4 and each transistor 31, 32, or 33 can be smoother, and the manufacturing process can proceed more smoothly.

Even in this case, since the second to fourth insulating layers 3b, 3c, and 3d include the reflective layers RF1, RF2, and RF3 and the gap-forming layers SC1, SC2, and SC3, respectively, it is possible to reduce or minimize a process error and a microcavity deviation, thereby improving the reliability of the display apparatus 1. In addition, since the hole injecting layer HIL may be separately patterned in each opening OP1, OP2, or OP3, it is possible to suppress or prevent a lateral leakage current between the adjacent sub-pixels 21, 22, and 23.

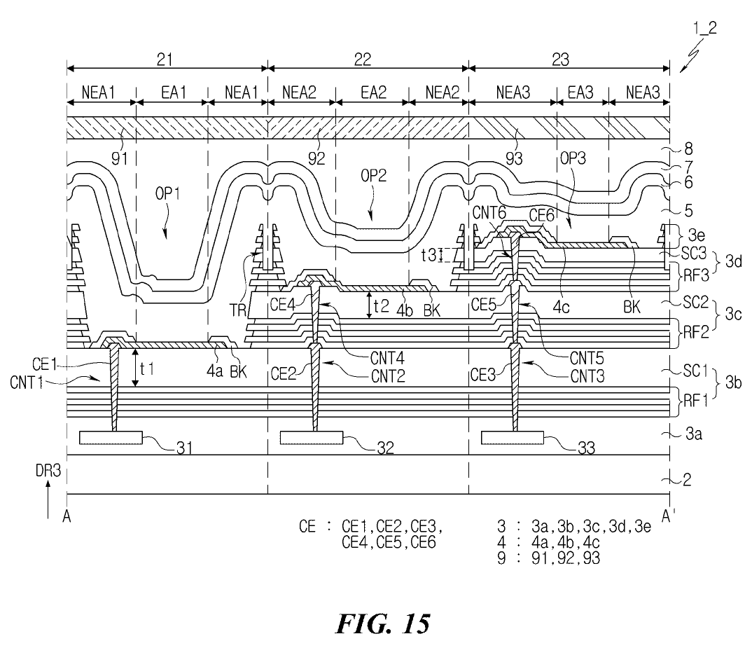

FIG. 15 is a cross-sectional view of a display apparatus according to still another embodiment.

Referring to FIG. 15, in a display apparatus 1_2 according to the present embodiment, in at least one of the sub-pixels 21, 22, and 23, the connection electrode CE (CE1, CE2, CE3, CE4, CE5, and CE6) connecting the anode electrodes 4a, 4b, and 4c to the transistors 31, 32, and 33 may be provided as a plurality of connection electrodes.

In the first sub-pixel 21, the first connection electrode CE1 may fill the first contact hole CNT1 passing through the second insulating layer 3b and a part of the first insulating layer 3a and come into contact with the first transistor 31. The first anode electrode 4a may cover the first connection electrode CE1 and come into contact with the first connection electrode CE1.

Through the first connection electrode CE1, the first anode electrode 4a and the first transistor 31 may be electrically connected.

In the second sub-pixel 22, the second connection electrode CE2 may fill the second contact hole CNT2 passing through the second insulating layer 3b and a part of the first insulating layer 3a and come into contact with the second transistor 32. A fourth connection electrode CE4 may fill a fourth contact hole CNT4 passing through the third insulating layer 3c and come into contact with the second connection electrode CE2. The second anode electrode 4b may cover a fourth connection electrode CE4 and come into contact with the fourth connection electrode CE4.

Through the second connection electrode CE2 and the fourth connection electrode CE4, the second anode electrode 4b and the second transistor 32 may be electrically connected.

In the third sub-pixel 23, the third connection electrode CE3 may fill the third contact hole CNT3 passing through the second insulating layer 3b and a part of the first insulating layer 3a and come into contact with the third transistor 33. A fifth connection electrode CE5 may fill a fifth contact hole CNT5 passing through the third insulating layer 3c and come into contact with the third connection electrode CE3. A sixth connection electrode CE6 may fill a sixth contact hole CNT6 passing through the fourth insulating layer 3d and come into contact with the fifth connection electrode CE5. The third anode electrode 4c may cover the sixth connection electrode CE6 and come into contact with the sixth connection electrode CE6.

Through the third connection electrode CE3, the fifth connection electrode CE5, and the sixth connection electrode CE6, the third anode electrode 4c and the third transistor 33 may be electrically connected.

Referring further to FIGS. 8 and 9, the first insulating layer 3a and the second insulating layer 3b may be sequentially disposed on the substrate 2, and then the second insulating layer 3b and the first insulating layer 3a may be etched to form the first contact hole CNT1, the second contact hole CNT2, and the third contact hole CNT3, and the deposited first conductive layer (not illustrated) may be patterned to form the first connection electrode CE1, the second connection electrode CE2, and the third connection electrode CE3.

Thereafter, the third insulating layer 3c may be disposed to cover the first connection electrode CE1, the second connection electrode CE2, and the third connection electrode CE3, the third insulating layer 3c may be etched to form the fourth contact hole CNT4 and the fifth contact hole CNT5, and a deposited second conductive layer (not illustrated) may be patterned to form the fourth connection electrode CE4 and the fifth connection electrode CE5.

Thereafter, the fourth insulating layer 3d may be disposed to cover the fourth connection electrode CE4 and the fifth connection electrode CE5, the fourth insulating layer 3d may be etched to form the sixth contact hole CNT6, and a deposited third conductive layer (not illustrated) may be patterned to form the sixth connection electrode CE6.

Thereafter, the fifth insulating layer 3e may be disposed to cover the sixth connection electrode CE6, and as illustrated in FIG. 9, the first to third openings OP1′, OP2′, and OP3′ may be formed to expose the connection electrodes CE1, CE4, and CE6, respectively.

In this case, since the anode electrode 4 and each transistor 31, 32, or 33 are connected by the connection electrode CE, the electrical connection between the anode electrode 4 and each transistor 31, 32, or 33 can be smoother, and the manufacturing process can proceed more smoothly.

Even in this case, since the second to fourth insulating layers 3b, 3c, and 3d include the reflective layers RF1, RF2, and RF3 and the gap-forming layers SC1, SC2, and SC3, respectively, it is possible to reduce or minimize a process error and a microcavity deviation, thereby improving the reliability of the display apparatus 1. In addition, since the hole injecting layer HIL may be separately patterned in each opening OP1, OP2, or OP3, it is possible to suppress or prevent a lateral leakage current between the adjacent sub-pixels 21, 22, and 23.

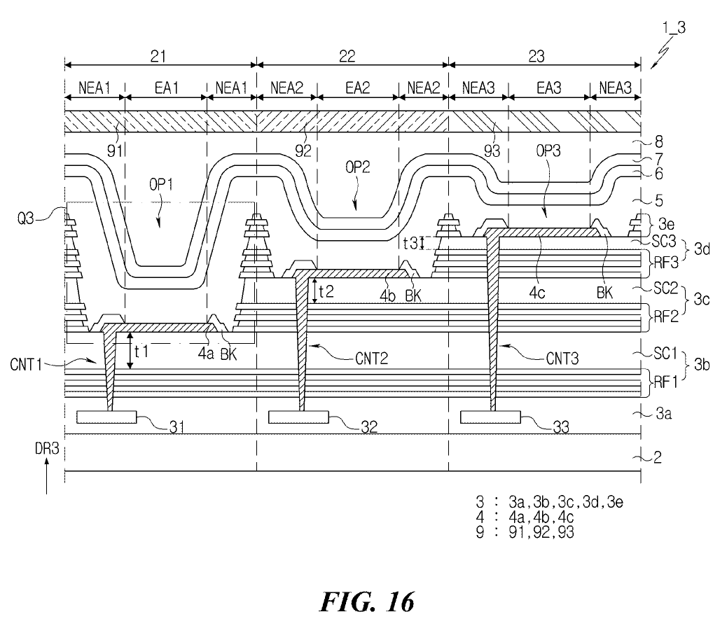

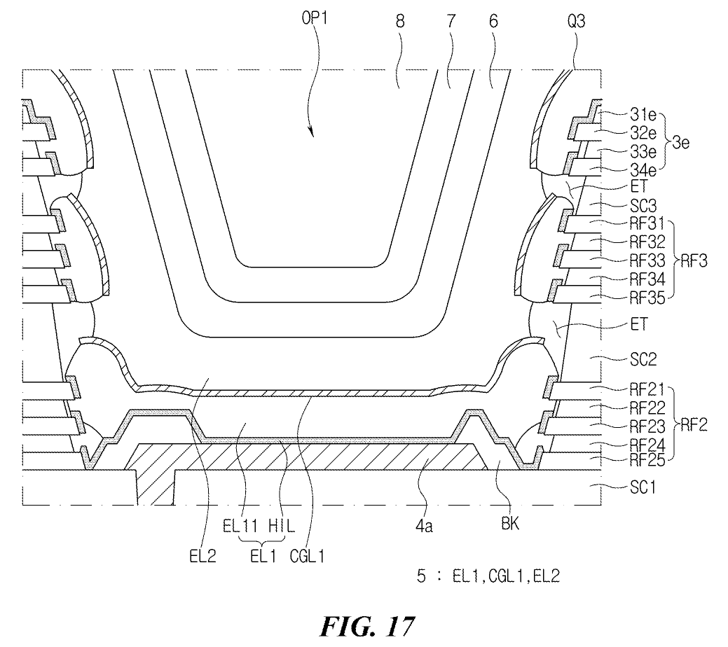

FIG. 16 is a cross-sectional view of a display apparatus according to yet another embodiment. FIG. 17 is an enlarged view of area Q3 in FIG. 16.

Referring to FIGS. 16 and 17, a display apparatus 1_3 according to the present embodiment includes the openings OP1, OP2, and OP3, and the side surface of the second gap-forming layer SC2 and the side surface of the third gap-forming layer SC3 forming the sidewalls of the openings OP1, OP2, and OP3 may be recessed more than the side surfaces of the inorganic films disposed adjacent thereto.

Specifically, in the first opening OP2, the side surface of the second gap-forming layer SC2 may be recessed more than the side surface of the 21^{st} inorganic layer RF21 and the side surface of the 35^{th} inorganic layer RF35 respectively disposed above and under the second gap-forming layer SC2. That is, in the first opening OP1, the side surface of the 21^{st} inorganic layer RF21 and the side surface of the 35^{th} inorganic layer RF35 may protrude toward the inside of the first opening OP1 more than the side surface of the second gap-forming layer SC2.

In the first opening OP1, the side surface of the third gap-forming layer SC3 may be recessed more than the side surface of the 31^{st} inorganic layer RF31 and the side surface of the fourth inorganic layer 34e respectively disposed above and under the third gap-forming layer SC3. That is, in the first opening OP1, the side surface of the 31^{st} inorganic layer RF31 and the side surface of the fourth inorganic layer 34e may protrude toward the inside of the first opening OP1 more than the side surface of the third gap-forming layer SC3.

Accordingly, in the first opening OP1, the first charge generation layer CGL1 disposed around the side surface of the second gap-forming layer SC2 and the side surface of the third gap-forming layer SC3 may be separately patterned.

A thickness of the second gap-forming layer SC2 and a thickness of the third gap-forming layer SC3 may be greater than a thickness of each of the inorganic films of the insulating layer 3. Accordingly, the gap between the side surface of the 21^{st} inorganic layer RF21 protruding from the side surface of the second gap-forming layer SC2 and the side surface of the 35^{th} inorganic layer RF35 may be increased.

The hole injecting layer HIL may be separated and the organic layer EL11 may also be separated in peripheral areas of the side surface of the second gap-forming layer SC2 and the side surface of the third gap-forming layer SC3. Accordingly, the first charge generation layer CGL1 disposed on the organic layer EL11 may be separated.

The first charge generation layer CGL1 may be disposed on the anode electrode 4a and the second reflective layer RF2, disposed on the third reflective layer RF3, and disposed on the fifth insulating layer 3e.

The first charge generation layer CGL1 disposed on the anode electrode 4a and the second reflective layer RF2, the first charge generation layer CGL1 disposed on the third reflective layer RF3, and the first charge generation layer CGL1 disposed on the fifth insulating layer 3e may be separately patterned and may not be electrically connected.

In the second opening OP2, the side surface of the third gap-forming layer SC3 may be recessed more than the side surface of the 31^{st} inorganic layer RF31 and the side surface of the fourth inorganic layer 34e respectively disposed above and under the third gap-forming layer SC3. That is, in the second opening OP2, the side surface of the 31^{st} inorganic layer RF31 and the side surface of the fourth inorganic layer 34e may protrude toward the inside of the second opening OP2 more than the side surface of the third gap-forming layer SC3.

Although not illustrated, as described in the first opening OP1, the hole injecting layer HIL may be separated and the organic layer EL11 may also be separated in a peripheral area of the side surface of the third gap-forming layer SC3 in the second opening OP2. Accordingly, the first charge generation layer CGL1 disposed on the organic layer EL11 may be separated.

The organic layer EL11 may not be disposed on at least a part of the side surface of the second gap-forming layer SC2. An empty space ET may be defined between the side surface of the second gap-forming layer SC2 on which the organic layer EL11 is not disposed and the second stack EL2.

The organic layer EL11 may not be disposed on at least a part of the side surface of the third gap-forming layer SC3. An empty space ET may be defined between the side surface of the third gap-forming layer SC3 on which the organic layer EL11 is not disposed and the second stack EL2.

Referring further to FIGS. 10 and 11, during the process of forming the openings OP1, OP2, and OP3 in the openings OP1′, OP2′, and OP3′, an etchant capable of selectively etching only parts of the inorganic layers of each of the third to fifth insulating layers 3c, 3d, and 3e is used to selectively etch only parts of the inorganic layers of each of the third to fifth insulating layers 3c, 3d, and 3e. During this process, the second gap-forming layer SC2 and the third gap-forming layer SC3 may be etched.

However, the method of forming each opening OP1, OP2, or OP3 of the embodiment according to FIG. 16 is not limited thereto. For example, by replacing materials of some of the inorganic layers of each of the third to fifth insulating layers 3c, 3d, and 3e with other materials or by changing the stacking order of the inorganic layers, each opening OP1, OP2, or OP3 of the embodiment according to FIG. 16 may be formed.

In the second opening OP2, the first charge generation layer CGL1 may be disposed on the anode electrode 4b and the third reflective layer RF3 and disposed on the fifth insulating layer 3e.

In the second opening OP2, each of the first charge generation layer CGL1 disposed on the anode electrode 4b and the third reflective layer RF3 and the first charge generation layer CGL1 disposed on the fifth insulating layer 3e may be separately patterned and may not be electrically connected.

Accordingly, even when the common light-emitting layer 5 is formed as a common layer across the first to third sub-pixels 21, 22, and 23, it is possible to suppress or prevent a lateral leakage current between the adjacent sub-pixels 21, 22, and 23, which may be generated by the first charge generation layer CGL1, by the sidewalls of the first and second openings OP1 and OP2.

In addition, since the first charge generation layer CGL1 is separated in the first and second openings OP1 and OP2, the trench TR may be unnecessary. Accordingly, it is possible to simplify the entire process.

Even in this case, since the second to fourth insulating layers 3b, 3c, and 3d include the reflective layers RF1, RF2, and RF3 and the gap-forming layers SC1, SC2, and SC3, respectively, it is possible to reduce or minimize a process error and a microcavity deviation, thereby improving the reliability of the display apparatus 1. In addition, since the hole injecting layer HIL may be separately patterned in each opening OP1, OP2, or OP3, it is possible to suppress or prevent a lateral leakage current between the adjacent sub-pixels 21, 22, and 23.

A display apparatus according to various embodiments of the present specification may be described as follows.

According to embodiments of the present specification, there is provided a display apparatus including a substrate having a first sub-pixel, a second sub-pixel, and a third sub-pixel, each of which includes a light-emitting area and a non-light-emitting area, a second insulating layer disposed on the substrate and including a first reflective layer and a first gap-forming layer, a first anode electrode disposed on the second insulating layer, a third insulating layer disposed on the second insulating layer, a fourth insulating layer disposed on the third insulating layer, a fifth insulating layer disposed on the fourth insulating layer, and a first opening passing through the third insulating layer, the fourth insulating layer, and the fifth insulating layer in the thickness direction to expose the first anode electrode and the second insulating layer in the first sub-pixel, in which the first reflective layer includes a plurality of inorganic films having different refractive indexes.

According to various embodiments of the present specification, the first gap-forming layer may be disposed between the first anode electrode and the first reflective layer, and the first reflective layer may be a distributed Bragg reflector (DBR).

According to various embodiments of the present specification, each of the third insulating layer, the fourth insulating layer, and the fifth insulating layer may include a plurality of inorganic layers forming a side surface of the first opening, and the plurality of inorganic layers may include a plurality of undercut areas including an undercut shape between adjacent inorganic layers on the side surface of the first opening.

According to various embodiments of the present specification, the plurality of inorganic layers of the third insulating layer, the fourth insulating layer, and the fifth insulating layer may be sequentially stacked in a thickness direction, and the plurality of inorganic layers may be formed so that a protruding inorganic layer of which a side surface protrudes toward the inside of the first opening and a recessed inorganic layer of which a side surface is recessed toward an outside of the first opening are alternately disposed.

According to various embodiments of the present specification, the plurality of undercut areas are provided in the thickness direction.

According to various embodiments of the present specification, the display apparatus may further include a second opening in the second sub-pixel that extends into the fourth insulating layer and the fifth insulating layer in the thickness direction to expose the third insulating layer, and a third opening in the third sub-pixel that extends into the fifth insulating layer in the thickness direction to expose the fourth insulating layer, in which the plurality of inorganic layers of each of the fourth insulating layer and the fifth insulating layer may form a side surface of the second opening, and the plurality of inorganic layers of each of the fourth insulating layer and the fifth insulating layer may have a plurality of undercut shapes between adjacent inorganic layers on the side surface of the second opening, and the plurality of inorganic layers of the fifth insulating layer may form a side surface of the third opening, and the plurality of inorganic layers of the fifth insulating layer may have a plurality of undercut shapes between adjacent inorganic layers on the side surface of the third opening.

According to various embodiments of the present specification, the display apparatus may further include a hole injecting layer disposed on the first anode electrode, in which the hole injecting layer may include a plurality of separated patterns in the plurality of under-cut areas in the first opening.

According to various embodiments of the present specification, an entire area of the first anode electrode may be disposed in the first opening.

According to various embodiments of the present specification, the display apparatus may further include a bank disposed on the first anode electrode and defining a light-emitting area and a non-light-emitting area, in which an entire area of the bank may be disposed in the first opening.

According to various embodiments of the present specification, the display apparatus may further include a second anode electrode disposed on the third insulating layer, and a second opening in the second sub-pixel that extends into the fourth insulating layer and the fifth insulating layer in the thickness direction to expose the second anode electrode and the third insulating layer, in which the third insulating layer may include a second reflective layer and a second gap-forming layer, and the second reflective layer may include a plurality of inorganic films having different refractive indexes.

According to various embodiments of the present specification, the second gap-forming layer may be disposed between the second anode electrode and the second reflective layer.

According to various embodiments of the present specification, the display apparatus may further include a third anode electrode disposed on the fourth insulating layer and a third opening in the third sub-pixel that extends into the fifth insulating layer in the thickness direction to expose the third anode electrode and the fourth insulating layer in the third sub-pixel, in which the fourth insulating layer may include a third reflective layer and a third gap-forming layer, and the third reflective layer may include a plurality of inorganic films having different refractive indexes.

According to various embodiments of the present specification, the third gap-forming layer may be disposed between the third anode electrode and the third reflective layer.

According to various embodiments of the present specification, a thickness of the first reflective layer may be greater than a thickness of the second reflective layer, and the thickness of the second reflective layer may be greater than a thickness of the third reflective layer.

According to various embodiments of the present specification, the second reflective layer and the third reflective layer may be distributed Bragg reflectors (DBRs).

According to various embodiments of the present specification, the display apparatus may further include a first insulating layer disposed between the substrate and the second insulating layer, and a transistor disposed in the first insulating layer and electrically connected to the first anode electrode.

According to embodiments of the present specification, there is provided a display apparatus including a substrate, a second insulating layer disposed on the substrate, an anode electrode disposed on the second insulating layer, a third insulating layer disposed on the second insulating layer, and an opening passing through the third insulating layer in the thickness direction to expose the anode electrode and the second insulating layer, in which the third insulating layer includes a plurality of inorganic layers forming a side surface of the opening, and the plurality of inorganic layers include a plurality of undercut areas including an undercut shape between adjacent inorganic layers on the side surface of the opening.

According to various embodiments of the present specification, the plurality of inorganic layers of the third insulating layer may be sequentially stacked in the thickness direction, and the plurality of inorganic layers may be formed so that a protruding inorganic layer of which a side surface protrudes toward an inside of the opening and a recessed inorganic layer of which a side surface is recessed toward an outside of the opening are alternately disposed.

According to various embodiments of the present specification, the display apparatus may further include a bank disposed on the anode electrode and defining a light-emitting area, in which the anode electrode may come into direct contact with an upper surface of the second insulating layer, the opening may expose the anode electrode and the bank, and an entire area of each of the anode electrode and the bank may be disposed in the opening.

According to various embodiments of the present specification, the second insulating layer may include a reflective layer and a gap-forming layer, the gap-forming layer may be disposed between the anode electrode and the reflective layer, and the reflective layer may be a distributed Bragg reflector including a plurality of inorganic films having different refractive indexes.

Although the embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus

2: substrate

3: insulating layer

RF: reflective layer

SC: gap-forming layer

4: anode electrode

5: common light-emitting layer

6: cathode electrode

7: capping layer

8: encapsulation layer

9: color filter layer

TR: trench

OP: opening

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate having a first sub-pixel, a second sub-pixel, and a third sub-pixel, each of which includes a light-emitting area and a non-light-emitting area;
a second insulating layer on the substrate, the second insulating layer including a first reflective layer and a firs gap-forming layer;
a first anode electrode on the second insulating layer;
a third insulating layer on the second insulating layer;
a fourth insulating layer on the third insulating layer;
a fifth insulating layer on the fourth insulating layer; and
a first opening in the first sub-pixel that extends into the third insulating layer, the fourth insulating layer, and the fifth insulating layer in a thickness direction and exposes the first anode electrode and the second insulating layer,
wherein the first reflective layer includes a plurality of inorganic films having different refractive indexes.

2. The display apparatus of claim 1, wherein the first gap-forming layer is between the first anode electrode and the first reflective layer, and
wherein the first reflective layer includes distributed Bragg reflectors (DBRs).

3. The display apparatus of claim 1, wherein each of the third insulating layer, the fourth insulating layer, and the fifth insulating layer includes a plurality of inorganic layers that define a side surface of the first opening, and
wherein the plurality of inorganic layers includes a plurality of undercut areas including an undercut shape between adjacent inorganic layers on the side surface of the first opening.

4. The display apparatus of claim 3, wherein the plurality of inorganic layers of the third insulating layer, the fourth insulating layer, and the fifth insulating layer are sequentially stacked in the thickness direction, and
wherein the plurality of inorganic layers is disposed so that a protruding inorganic layer of which a side surface protrudes toward an inside of the first opening and a recessed inorganic layer of which a side surface is recessed toward an outside of the first opening are alternately disposed.

5. The display apparatus of claim 4, wherein the plurality of undercut areas is provided in the thickness direction.

6. The display apparatus of claim 3, further comprising:
a second opening in the second sub-pixel that extends into the fourth insulating layer and the fifth insulating layer in the thickness direction to expose the third insulating layer; and
a third opening in the third sub-pixel that extends into the fifth insulating layer in the thickness direction to expose the fourth insulating layer,
wherein the plurality of inorganic layers of each of the fourth insulating layer and the fifth insulating layer form a side surface of the second opening,
wherein the plurality of inorganic layers of each of the fourth insulating layer and the fifth insulating layer form a plurality of undercut shapes between adjacent inorganic layers on the side surface of the second opening,
wherein the plurality of inorganic layers of the fifth insulating layer define a side surface of the third opening, and
wherein the plurality of inorganic layers of the fifth insulating layer define a plurality of undercut shapes between adjacent inorganic layers on the side surface of the third opening.

7. The display apparatus of claim 3, further comprising a hole injecting layer on the first anode electrode,
wherein the hole injecting layer includes a plurality of separated patterns in the plurality of under-cut areas in the first opening.

8. The display apparatus of claim 1, wherein an entire area of the first anode electrode is disposed in the first opening.

9. The display apparatus of claim 8, further comprising a bank on the first anode electrode and defining the light-emitting area and the non-light-emitting area,
wherein an entire area of the bank is disposed in the first opening in the first sub-pixel.

10. The display apparatus of claim 1, further comprising:
a second anode electrode disposed on the third insulating layer; and
a second opening in the second sub-pixel that extends into the fourth insulating layer and the fifth insulating layer in the thickness direction to expose the second anode electrode and the third insulating layer,
wherein the third insulating layer includes a second reflective layer and a second gap-forming layer, and
wherein the second reflective layer includes a plurality of inorganic films having different refractive indexes.

11. The display apparatus of claim 10, wherein the second gap-forming layer is between the second anode electrode and the second reflective layer.

12. The display apparatus of claim 10, further comprising:
a third anode electrode on the fourth insulating layer; and
a third opening in the third sub-pixel that extends into the fifth insulating layer in the thickness direction to expose the third anode electrode and the fourth insulating layer,
wherein the fourth insulating layer includes a third reflective layer and a third gap-forming layer, and
wherein the third reflective layer includes a plurality of inorganic films having different refractive indexes.

13. The display apparatus of claim 12, wherein the third gap-forming layer is between the third anode electrode and the third reflective layer.

14. The display apparatus of claim 12, wherein a thickness of the first reflective layer is greater than a thickness of the second reflective layer, and the thickness of the second reflective layer is greater than a thickness of the third reflective layer.

15. The display apparatus of claim 12, wherein the second reflective layer and the third reflective layer are distributed Bragg reflectors (DBRs).

16. The display apparatus of claim 1, further comprising:
a first insulating layer between the substrate and the second insulating layer; and
a transistor in the first insulating layer and electrically connected to the first anode electrode.

17. A display apparatus comprising:
a substrate;
a second insulating layer on the substrate;
an anode electrode on the second insulating layer;
a third insulating layer on the second insulating layer; and
an opening that extends into the third insulating layer in a thickness direction to expose the anode electrode and the second insulating layer,
wherein the third insulating layer includes a plurality of inorganic layers that define a side surface of the opening, and
wherein the plurality of inorganic layers includes a plurality of undercut areas including an undercut shape between adjacent inorganic layers on the side surface of the opening.

18. The display apparatus of claim 17, wherein the plurality of inorganic layers of the third insulating layer are sequentially stacked in the thickness direction, and
wherein the plurality of inorganic layers is disposed so that a protruding inorganic layer of which a side surface protrudes toward an inside of the opening and a recessed inorganic layer of which a side surface is recessed toward an outside of the opening are alternately disposed.

19. The display apparatus of claim 17, further comprising a bank on the anode electrode to define a light-emitting area,
wherein the anode electrode comes into direct contact with an upper surface of the second insulating layer,
wherein the opening exposes the anode electrode and the bank, and
wherein an entire area of each of the anode electrode and the bank is disposed in the opening.

20. The display apparatus of claim 17, wherein the second insulating layer includes a reflective layer and a gap-forming layer,
wherein the gap-forming layer is between the anode electrode and the reflective layer, and
wherein the reflective layer includes a plurality of inorganic films having different refractive indexes.
